(19) United States
(12) Patent Application Publication
(10) Pub. No.: US 2025/0354030 A1
(43) Pub. Date: Nov. 20, 2025

(54) CURABLE SILICONE-BASED GEL COMPOSITION, CURED GEL THEREOF, ENCAPSULANT AGENT, ELECTRONIC ARTICLE AND PROTECTION METHOD FOR SEMICONDUCTOR CHIP

(71) Applicant: DOW SILICONES CORPORATION, Midland, MI (US)

(72) Inventors: Ryan THOMAS, Midland, MI (US); Myoungbae LEE, Midland, MI (US); Michael WHITBRODT, Midland, MI (US)

(21) Appl. No.: 18/995,687

(22) PCT Filed: Jul. 20, 2023
(86) PCT No.: PCT/US2023/028237

§ 371 Date: Jan. 16, 2025

Related U.S. Application Data
(60) Provisional application No. 63/391,137, filed on Jul. 21, 2022.

(51) Int. Cl. C09D 183/06; H01L 23/29

(52) U.S. Cl. CPC C09D 183/06; H01L 23/295

(57) ABSTRACT

[Problem] To provide a curable silicone-based gel composition to form silicone-based gel with excellent thermal stability under high temperature and damping property to protect semiconductor-chip from mechanical shock and vibration. [Solution] A curable silicone-based gel composition comprising: (A) an organopolysiloxane resin having a mass loss when component (A) is exposed for 1 hour at 200° C. of 2.0 mass % or less, the (A) organopolysiloxane resin not having hydrosilylation-reactive groups; (B) a linear organopolysiloxane having alkenyl-group-terminals; (C) a linear organohydrogenpolysiloxane SiH-terminals; (D) Q-branched organopolysiloxane having at least three of silicon-bonded alkenyl groups on its molecular terminals; and (E) a hydrosilylation reaction catalyst.

### CROSS-REFERENCE TO RELATED APPLICATIONS

The application claims priority to and all advantages of U.S. Provisional Patent Application No. 63/391,137 filed on 21 Jul. 2022, the content of which is incorporated herein by reference.

### FIELD OF THE DISCLOSURE

The present disclosure generally relates to a curable silicone-based gel composition and silicone-based gel for use in sealing or filling of electrical or electronic parts as an encapsulating agent for an electronic article, and more specifically relates to a curable silicone-based gel composition that can form a silicone-based gel which, compared to conventional known silicone gels, has excellent thermal stability that can suppress the occurrence of cracks in the silicone gel caused from high temperatures of more than 200° C. for hundreds of hours or thermal shock, and having excellent damping property to protect a semiconductor chip from mechanical shock and vibration, which is derived from reduced crosslinking density in the cured silicone-based gel.

### BACKGROUND

Silicone gels are known in the art and can protect electronic components against moisture, dirt, shock, vibration and other harsh environmental factors, therefore extending service life and reliability. As a result, silicone gels are often used to seal and protect electronic system assemblies, particularly those with delicate components. Silicone gels are commercially delivered as 1-part or 2-part liquid formulations, which are then dispensed and cured in place to form a networked elastomeric silicone gel. Hydrosilylation chemistry is typically the incumbent reaction of choice for silicone gels, and therefore cure may be achieved at room temperature or utilize thermal acceleration. Silicone gels combine the stress relief qualities of a fluid with the dimensional stability of an elastomer and minimal shrinkage in a solventless and byproduct free solution.

Silicone gel compositions have been widely used to prepare silicone gels for use as sealants and fillers for electrical or electronic parts. Given the myriad conditions and industries in which such electrical or electronic parts are utilized, it is increasingly desirable for silicone gels to have excellent thermal stability, including at temperatures of 200° C. However, conventional silicone gels are prone to cracking upon prolonged exposure to such elevated temperatures, which is undesirable.

One effort to improve thermal stability of conventional silicone gels is to incorporate non-functional polydimethylsiloxanes, which reduce cross-link density. However, though use of non-functional polydimethylsiloxanes can reduce cross-link density of conventional silicone gels, their use also undesirably impacts other performance properties of conventional silicone gels, such as modulus. Another effort has been to incorporate functional resins into silicone gel compositions, which become part of the crosslinked matrix of the silicone gel formed by curing. Though use of functional resins provides desirable modulus, their use has not provided sufficient thermal stability and resistance to cracking at elevated temperatures.

### BRIEF SUMMARY

A curable silicone-based gel composition is disclosed, which comprises (A) an organopolysiloxane resin having a mass loss when component (A) is exposed for 1 hour at 200° C. of 2.0 mass % or less, and represented by following formula:

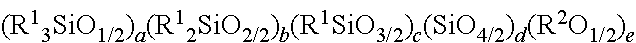

wherein each R¹ is independently a monovalent hydrocarbon group having 1 to 10 carbon atoms and not having alphatic unsaturation in the group; each R₂ is independently a hydrogen atom, or an alkyl group having 1 to 10 carbon atoms; and a, b, c, d and e are numbers satisfying the following: 0.10≤a≤0.60, 0.0≤b≤0.70, 0.0≤c≤0.80, 0.10≤d≤0.65, 0≤e≤0.05, and a+b+c+d=1). The composition further comprises (B) a linear organopolysiloxane having two silicon-bonded alkenyl groups only on its molecular teminals and represented by following formula:

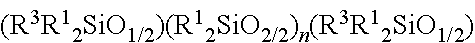

wherein each R¹ is independently selected and defined above; each R³ is independently an alkenyl group having 2 to 10 carbon atoms; and subscript n is a number from 10 to 1000. The composition additionally comprises (C) a linear organohydrogenpolysiloxane having two silicon-bonded hydrogen atoms only on its molecular terminals and a viscosity at 25° C. of 2 to 10,000 mPa·s. Further, the composition comprises (D) a Q-branched organopolysiloxane having at least three silicon-bonded alkenyl groups on its molecular terminals and represented by the following formula:

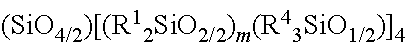

wherein each R¹ is independently selected and defined above; each R⁴ is independently R¹ or an alkenyl group having 2 to 10 carbon atoms with the proviso that at least three of R⁴ are alkenyl groups; and each m is independently a number from 5 to 200. Finally, the composition comprises (E) a hydrosilylation reaction catalyst in an amount satisfying the curing reaction among components (A) to (D).

An encapsulant agent for an electronic article comprising the curable silicone-based gel composition is also disclosed, along with a silicone-based gel prepared by curing the curable silicone-based gel composition.

An electronic article comprising the encapsulant agent or the silicone-based gel is further provided.

Finally, a protection method for a semiconductor chip is provided, which is characterized by using the curable silicone-based gel composition, the encapsulant agent, or the silicone-based gel to protect a semiconductor chip.

### Problem to be Solved

As electronic assembly units are becoming progressively more complex and power density demands are on the rise, the need for better damping properties and thermal stability requirements of silicone gel materials are increasing.

Most conventional silicone gel materials can ensure reliable performance up to 150° C., but industry is increasing seeking silicone gel materials having stability at temperatures up to 200° C. Conventional silicone gel materials show signs of failure under such conditions, including the formation of cracks or voids, which can compromise performance.

Damping properties of silicone gels provide a degree of protection against mechanical shock and vibration. Damping properties can be improved by reducing a crosslink density of a silicone gel. Incorporation of non-functional ingredients, such as trimethylsiloxy endblocked polydimethylsiloxane, is one of the technical approaches to reduce the crosslink density; however, the technical approach is commonly accompanied by the compromise of other properties such as storage modulus (G′), which represents the material's stiffness. As such, efforts to improve damping properties have resulted in undesirable impact to storage modulus and other performance properties.

### Means for Solving the Problem

As a result of intensive investigation, the present inventors have found that the problems described above can be resolved by a composition comprising: (A) organopolysiloxane resin that does not have hydrosilylation-reactive groups and having a mass loss when exposed for 1 hour at 200 C of 2.0 mass % or less in combination wifth (B) a linear organopolysiloxane having two silicon-bonded alkenyl groups only on its molecular terminals; (C) a linear organohydrogenpolysiloxane having two silicon-bonded hydrogen atoms only on its molecular terminals and a viscosity at 25° C. of 2 to 10,000 mPa·s; (D) a Q-branched organopolysiloxane having at least three silicon-bonded alkenyl groups on its molecular terminals; and (E) a hydrosilylation reaction catalyst.

### Effect of the Invention

The curable silicone-based gel composition of the present invention can be cured into a silicone-based gel which is excellent in thermal stability under high temperature and damping property to protect semiconductor chip from mechanical shock or vibration. Therefore, this curable silicone-based gel composition can be used as an encapsulant agent applied to or for an electronic article, and an electronic article having the encapsulant agent or the silicone-based gel is provided. Also, this invention can provide a protection method for semiconductor chip, which is characterized by using the curable silicone-based gel composition, the encapsulant agent applied for electronic article or the silicone-based gel.

### BRIEF DESCRIPTION OF THE DRAWINGS

Various advantages and aspects of this disclosure may be understood in view of the following detailed description when considered in connection with the accompanying drawing, wherein:

FIG. 1 shows the cured silicone gels of Examples 1-3 (as shown by “INV1” to “INV3”), both initially and after thermal aging for 744 hours with crack-free state;

FIG. 2 shows the cured silicone gels of Examples 4-7 (as shown by “INV4” to “INV7”), both initially and after thermal aging for 744 hours with crack-free state; and

FIG. 3 shows the cured silicone gels of Comparative Examples 1-3 (as shown by “Comp1” to “Comp3”), both initially and after thermal aging for 744 hours (with cracked state after aging).

### DETAILED DESCRIPTION

The present disclosure provides a curable silicone-based gel composition. The composition can be cured to give a silicone-based gel having excellent physical properties, including thermal stability and damping properties. As such, the composition is particularly well suited for use in or as an encapsulant for electronic components and articles. However, end uses of the composition and silicone-based gel formed therewith are not so limited. Furthermore, the composition of the present disclosure is also characterized by having hot-melt properties as a whole. In this disclosure, unless otherwise stated, “having hot-melt properties” means having a softening point of 50 to 200° C., having a melt viscosity at 150° C. (suitably, a melt viscosity of less than 1,000 Pa·s), and having flowing properties.

The composition of the present invention contains (A) an organopolysiloxane resin represented by following formula:

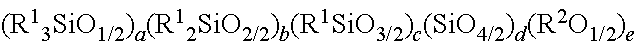

where each R¹ is independently a monovalent hydrocarbon group having 1 to 10 carbon atoms and not having aliphatic unsaturation in the group; each R₂ is independently a hydrogen atom, or an alkyl group having 1 to 10 carbon atoms; and a, b, c, d and e are numbers satisfying the following: 0.10≤a≤0.60, 0.0≤b≤0.70, 0.0≤c≤0.80, 0.10≤d≤0.65, 0≤e≤0.05, and a+b+C+d=1).

As understood by those of skill in the art, organopolysiloxane resins comprise inorganic silicon-oxygen-silicon groups (i.e., —Si—O—Si—), with organosilicon and/or organic side groups attached to the silicon atoms in M, D, and T siloxy units. Organopolysiloxane resins are typically characterized in terms of the number, type, and/or proportion of [M], [D], [T], and/or [Q] units/siloxy groups, which each represent structural units of individual functionality present in organopolysiloxane resins. In particular, [M] represents a monofunctional unit of general formula R″₃SiO_{1/2}; [D] represents a difunctional unit of general formula R″₂SiO_{2/2}; [T] represents a trifunctional unit of general formula R″SiO_{3/2}; and [Q] represents a tetrafunctional unit of general formula SiO_{4/2}, as shown by the general structural moieties below:

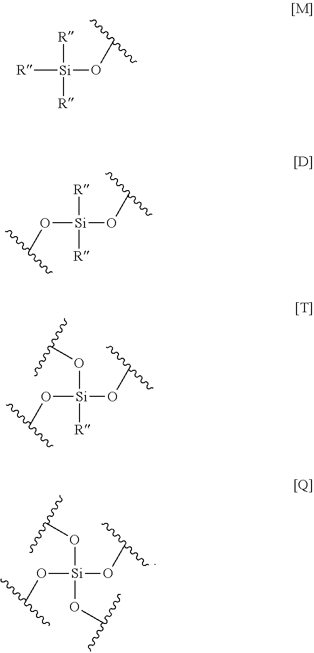

In these general structural moieties, each R″ is independently a monovalent or polyvalent substituent. As understood in the art, specific substituents suitable for each R″ are not particularly limited (e.g. may be monoatomic or polyatomic, organic or inorganic, linear or branched, substituted or unsubstituted, aromatic, aliphatic, saturated or unsaturated, etc., as well as various combinations thereof).

One of skill in the art understands how [M], [D], [T] and [Q] units, and their relative proportions (i.e., molar fractions) influence and control the structure of siloxanes, and that polysiloxanes in general may be monomeric, polymeric, oligomeric, linear, branched, cyclic, and/or resinous depending on the selection of [M], [D], [T] and/or [Q] units therein. For example, [T] units and/or [Q] units are present in organopolysiloxane resins, whereas linear organopolysiloxanes are typically free from such [T] units and/or [Q] units.

In the (A) organopolysiloxane resin, each R¹ is independently a monovalent hydrocarbon group having 1 to 10 carbon atoms and not having aliphatic unsaturation in the group. Thus, each R¹ is not an alkenyl or alkynyl group. The (A) organopolysiloxane is generally free from functional groups that are hydrosilylatable (i.e., silicon-bonded ethylenically unsaturated groups and silicon-bonded hydrogen atoms). In general, monovalent hydrocarbon groups suitable for R¹ may independently be linear, branched, cyclic, or combinations thereof. Cyclic hydrocarbyl groups encompass aryl groups as well as saturated or non-conjugated cyclic groups. Cyclic hydrocarbyl groups may independently be monocyclic or polycyclic. One example of a combination of a linear and cyclic hydrocarbyl group is an aralkyl group. General examples of monovalent hydrocarbon groups free from aliphatic unsaturation include alkyl groups, aryl groups, halocarbon groups, and the like, as well as derivatives, modifications, and combinations thereof. Examples of suitable alkyl groups include methyl, ethyl, propyl (e.g. iso-propyl and/or n-propyl), butyl (e.g. isobutyl, n-butyl, tert-butyl, and/or sec-butyl), pentyl (e.g. isopentyl, neopentyl, and/or tert-pentyl), hexyl, heptyl, octyl, etc. Examples of suitable non-conjugated cyclic groups include cyclobutyl, cyclohexyl, and cycyloheptyl groups. Examples of suitable aryl groups include phenyl, tolyl, xylyl, naphthyl, benzyl, and dimethyl phenyl. Examples of suitable monovalent halogenated hydrocarbon groups (i.e., halocarbon groups) include halogenated alkyl groups, aryl groups, and combinations thereof. Examples of halogenated alkyl groups include the alkyl groups described above where one or more hydrogen atoms is replaced with a halogen atom such as F or Cl. Specific examples of halogenated alkyl groups include fluoromethyl, 2-fluoropropyl, 3,3,3-trifluoropropyl, 4,4,4-trifluorobutyl, 4,4,4,3,3-pentafluorobutyl, 5,5,5,4,4,3,3-heptafluoropentyl, 6,6,6,5,5,4,4,3,3-nonafluorohexyl, and 8,8,8,7,7-pentafluorooctyl, 2,2-difluorocyclopropyl, 2,3-difluorocyclobutyl, 3,4-difluorocyclohexyl, and 3,4-difluoro-5-methylcycloheptyl, chloromethyl, chloropropyl, 2-dichlorocyclopropyl, and 2,3-dichlorocyclopentyl groups, as well as derivatives thereof. Examples of halogenated aryl groups include the aryl groups described above where one or more hydrogen atoms is replaced with a halogen atom, such as F or Cl. Specific examples of halogenated aryl groups include chlorobenzyl and fluorobenzyl groups. In specific embodiments, each R¹ is independently selected from alkyl groups having from 1 to 10, alternatively from 1 to 8, alternatively from 1 to 6, alternatively from 1 to 4, alternatively from 1 to 2, alternatively 1, carbon atom(s).

Moieties represented by (R²O_{1/2}) are typically inherently present when the (A) organopolysiloxane resin is prepared via hydrolysis and condensation of silanes. For example, a Q siloxy unit precursor may not fully condense when preparing the (A) organopolysiloxane resin, thus resulting in a T siloxy unit including an Si—OR² moiety instead of four siloxane bonds. Moieties represented by (R²O_{1/2}) may be absent from the (A) organopolysiloxane resin depending on its method of preparation.

As described above, subscripts a, b, c, d and e are numbers satisfying the following: 0.10≤a≤0.60, 0.0≤b≤0.70, 0.0≤c≤0.80, 0.10≤d≤0.65, 0≤e≤0.05, and a+b+c+d=1. In specific embodiments, 0.10≤a≤0.60, alternatively 0.15≤a≤0.60, alternatively 0.20≤a≤0.60, alternatively 0.25≤a≤0.60, alternatively 0.30≤a≤0.60, alternatively 0.35≤a≤0.60, alternatively 0.40≤a≤0.60, alternatively 0.40≤a≤0.55. In these or other embodiments, 0.0≤b≤0.70, alternatively 0.0≤b≤0.60, alternatively 0.0≤b≤0.50, alternatively 0.0≤b≤0.40, alternatively 0.0≤b≤0.30, alternatively 0.0≤b≤0.20, alternatively 0.0≤b≤0.10, alternatively 0.0≤b≤0.05, alternatively 0.0<b≤0.05, alternatively b is 0. In these or other embodiments, 0.0≤c≤0.80, alternatively 0.0≤c≤0.70, alternatively 0.0≤c≤0.60, alternatively 0.0≤c≤0.50, alternatively 0.0≤c≤0.40, alternatively 0.0≤c≤0.30, alternatively 0.0≤c≤0.20, alternatively 0.0≤c≤0.10, alternatively 0.0≤c≤0.05, alternatively 0.0<c≤0.05, alternatively c is 0. In these or other embodiments, 0.10≤d≤0.65, alternatively 0.15≤d≤0.65, alternatively 0.20≤d≤0.65, alternatively 0.25≤d≤0.65, alternatively 0.30≤d≤0.65, alternatively 0.35≤d≤0.65, alternatively 0.40≤d≤0.60, alternatively 0.45≤d≤0.55. In these or other embodiments, 0.0≤e≤0.05, alternatively 0.0<e≤0.05, alternatively e is 0.

As will be appreciated in view of the description herein, in specific embodiments, the (A) organopolysiloxane resin may be categorized or otherwise referred to as an MQ resin where, as introduced above, M designates monofunctional siloxy units and Q designates tetrafunctional siloxy units (i.e., SiO_{4/2}). Such MQ resins are known in the art as macromolecular polymers composed primarily of M and Q units and, optionally a limited number of D and/or T units (e.g. ≤20, alternatively ≤15, alternatively ≤10, alternatively ≤5 mole %, total), and typically present in/as a solid (e.g. powder or flake) form unless disposed in a solvent. These MQ resins are often designated simply by the general formula [M]ₓ[Q] where subscript x refers to the molar ratio of M siloxy units to Q siloxy units when the number of moles of Q siloxy units is normalized to 1. In such instances, the greater the value of x, the lesser the crosslink density of MQ resin. The inverse is also true as, when the value of x decreases, the number of M siloxy units decreases, and thus more Q siloxy units are networked without termination via an M siloxy unit. It will be appreciated, however, that the normalized content of Q siloxy units does not imply or limit MQ resins to only one Q unit. Rather, MQ resins typically includes a plurality of Q siloxy units clustered or bonded together. In certain embodiments when the (A) organopolysiloxane resin is an MQ resin, x is from 0.5 to 1.5, alternatively from 0.6 to 1.4, alternatively from 0.7 to 1.3, alternatively from 0.8 to 1.2, alternatively from 0.9 to 1.1.

In certain embodiments, the (A) organopolysiloxane has a weight-average molecular weight (M_{w}) of from greater than 1,000 to 100,000, alternatively from greater than 5,000 to 50,000, alternatively from 10,000 to 30,000, alternatively from 14,000 to 20,000, g/mol. The weight-average molecular weight may be readily determined using Gel Permeation Chromatography (GPC) techniques based on polystyrene standards.

Component (A) has a mass loss when exposed for 1 hour at 200° C. that is 2.0 mass % or less. The mass loss rate of component (A) when exposed for 1 hour at 200° C. of 2.0 mass % or less means that the amount of volatile component of component (A) is low. The (A) organopolysiloxane resin has a high content of a specific branched siloxane unit (SiO_{4/2}), or Q siloxy units, where the amount of volatile components in component (A) is very low. Specifically, the mass loss rate of component (A) is 2.0 mass % or less when exposed to 200° C. for 1 hour, alternatively 1.5 mass % or less, alternatively 1.0 mass % or less. The mass loss is simply measured based on the mass of component (A) prior to exposing component (A) to a temperature of 200° C. for 1 hour as compared to the mass after exposing component (A) to a temperature 200° C. for 1 hour. Said differently, the mass loss is the total mass lost by component (A), if any, after exposing component (A) to a temperature 200° C. for 1 hour. Typically, exposing conventional organopolysiloxane resins to elevated temperatures causes a reduction in mass. There are no specific requirements for exposing component (A) to a temperature of 200° C. for 1 hour to determine mass loss. Any source of heat may be utilized, e.g. an oven. Ambient conditions can otherwise be utilized, e.g. component (A) may be exposure to air, atmospheric pressure, relative humidity, etc. while heating component (A). In specific embodiments, no ambient conditions other than temperature are controlled when measuring mass loss of component (A). The mass loss of component (A) is measured based on the organopolysiloxane resin of component (A) in neat form, i.e., any vehicle or solvent present in component (A) is removed prior to measuring or determining mass loss, as volatilization of any vehicle or solvent is not considered to influence the mass loss of component (A). In specific embodiments, mass loss of component (A) is based solely on silicon-based compound which volatilize from component (A) upon exposure to a temperature of 200° C. for 1 hour. Silicon-based compounds are any compounds including a silicon atom.

For example, generally, in the production process of conventional organopolysiloxane resins containing a large number of branched siloxane units, volatile low molecular weight components are generated as byproducts from condensation of silane compounds, which byproducts are physically mixed into and with conventional organopolysiloxane resins. For example, the conventional organopolysiloxane resins often serve as a physical matrix containing the byproducts. These byproducts, especially small molecules having few siloxy units, are considered volatile components. However, these volatile components have the effect of greatly reducing the hardness of a cured product obtained from curing a composition containing such conventional organopolysilxoane resins, as the volatile components do not contribute to curing or crosslink density. As a result, when the cured product is exposed to a temperature exceeding 150° C. for a long period of time, the byproducts contained in or with the conventional organopolysiloxane resins will volatilize and, as a result, the hardness of the cured product is significantly decreased. Furthermore, when the network of the cured product contains a large amount of siloxane units as expressed by SiO_{4/2}, the cured product tends to be extremely brittle in terms of hardness, and consequently, embrittlement also occurs.

By employing the (A) organopolysiloxane resin in the composition, a cured product that is not prone to increasing hardness and embrittlement even when exposed to a temperature exceeding 150° C. for a long period of time can be provided. Therefore, when the mass loss of component (A) when exposed for 1 hour at 200° C. exceeds the upper limit, the hardness of the obtained cured product dramatically increases, particularly at high temperatures, and embrittlement tends to occur. Note that the lower limit of the mass loss rate of component (A) is typically 0.0 mass % or not containing volatile low molecular weight components, but the hardness change of the cured product can be sufficiently suppressed in practical use in a range of 0.1 to 2.0 mass %, in a range of 0.2 to 1.5 mass %, and in a range of 0.3 to 0.8 mass %. When the mass loss rate of component (A) is 0.0 mass %, component (A) may consist essentially of, alternatively consist of, the organopolysiloxane resin.

The species of the volatile low molecular weight component is not particularly limited, but since the organopolysiloxane resin of the present invention contains a large number of branched siloxane units (Q units) expressed as SiO_{4/2}, the volatile siloxane component as expressed by M₄Q is easily generated as a byproduct by a reaction with the siloxane units (M units) expressed as R₃SiO_{1/2}, where R is typically a hydrocarbyl group, typically an alkyl group. In the present invention, it is typical that the aforementioned mass reduction rate is achieved by removing the volatile low molecular weight component or volatile siloxane component from the (A) organopolysiloxane resin to give component (A).

Component (A) may comprise a combination or two or more different organopolysiloxane resins that differ in at least one property such as structure, molecular weight, monovalent groups bonded to silicon atoms, etc.

In certain embodiments, component (A) may further comprise a vehicle to carry, solubilize, or partially solubilize the organopolysiloxane resin. The vehicle, if utilized, is typically an organic fluid, which generally comprises an organic oil including a volatile and/or semi-volatile hydrocarbon, ester, and/or ether. General examples of such organic fluids include volatile hydrocarbon oils, such as C₆-C₁₆ alkanes, C₈-C₁₆ isoalkanes (e.g. isodecane, isododecane, isohexadecane, etc.) C₈-C₁₆ branched esters (e.g. isohexyl neopentanoate, isodecyl neopentanoate, etc.), and the like, as well as derivatives, modifications, and combinations thereof. Additional examples of suitable organic fluids include aromatic hydrocarbons, aliphatic hydrocarbons, alcohols having more than 3 carbon atoms, aldehydes, ketones, amines, esters, ethers, glycols, glycol ethers, alkyl halides, aromatic halides, and combinations thereof. Hydrocarbons include isododecane, isohexadecane, Isopar L (C₁₁-C₁₃), Isopar H (C₁₁-C₁₂), hydrogenated polydecene. Ethers and esters include isodecyl neopentanoate, neopentylglycol heptanoate, glycol distearate, dicaprylyl carbonate, diethylhexyl carbonate, propylene glycol n-butyl ether, ethyl-3 ethoxypropionate, propylene glycol methyl ether acetate, tridecyl neopentanoate, propylene glycol methylether acetate (PGMEA), propylene glycol methylether (PGME), octyldodecyl neopentanoate, diisobutyl adipate, diisopropyl adipate, propylene glycol dicaprylate/dicaprate, octyl ether, octyl palmitate, and combinations thereof.

In some embodiments, the vehicle comprises, alternatively is, an organic solvent. Examples of the organic solvent include those comprising an alcohol, such as methanol, ethanol, isopropanol, butanol, and n-propanol; a ketone, such as acetone, methylethyl ketone, and methyl isobutyl ketone; an aromatic hydrocarbon, such as benzene, toluene, and xylene; an aliphatic hydrocarbon, such as heptane, hexane, and octane; a glycol ether, such as propylene glycol methyl ether, dipropylene glycol methyl ether, propylene glycol n-butyl ether, propylene glycol n-propyl ether, and ethylene glycol n-butyl ether; a halogenated hydrocarbon, such as dichloromethane, 1,1,1-trichloroethane and methylene chloride; chloroform; dimethyl sulfoxide; dimethyl formamide, acetonitrile; tetrahydrofuran; white spirits; mineral spirits; naphtha; n-methylpyrrolidone; and the like, as well as derivatives, modifications, and combination thereof.

The amount of the vehicle present in component (A) depends on various factors (e.g. the selection of the organopolysiloxane resin, curing conditions to which the composition is intended to be exposed, etc.), and may be readily determined by one of skill in the art. In general, where present, component (A) comprises the vehicle in an amount of from 1 to 50, alternatively from 20 to 50, alternatively from 30 to 40, wt. %, based on the total weight of component (A). Typically, however, component (A) is free from the vehicle and the organopolysiloxane resin is utilized in neat or dry form in the composition. Alternatively still, component (A) may initially include the vehicle, and the vehicle may be removed from component (A) and/or the composition during preparation of the composition prior to an end use thereof.

The composition typically comprises component (A) in an amount of from 1 to 40, alternatively from 2 to 40, alternatively from 3 to 40, alternatively from 4 to 40, alternatively from 5 to 40, alternatively from 6 to 40, alternatively from 3 to 30, alternatively from 4 to 30, alternatively from 5 to 30, alternatively from 6 to 30, weight percent based on the total weight of the composition. These weight ranges are typically based solely on the organopolysiloxane resin of component (A), and not any vehicle that may be present in component (A).

The composition further comprises (B) a linear organopolysiloxane having two silicon-bonded alkenyl groups only on its molecular terminals. Said differently, component (B) does not include silicon-bonded alkenyl groups in pendant positions, i.e., bonded to silicon atoms in D siloxy units. The linear organopolysiloxane is represented by following formula:

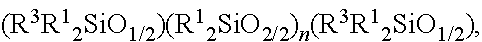

where each R¹ is independently selected and defined above; each R³ is independently an alkenyl group having 2 to 10 carbon atoms; and n is a number from 10 to 1000. As shown by the formula above, each terminal M unit of the linear organopolysiloxane of component (B) includes one alkenyl group, i.e., the linear organopolysiloxane has two silicon-bonded alkenyl groups in total, not at each molecular terminal.

With reference to R³, “alkenyl” means an acyclic, branched or unbranched, monovalent hydrocarbon group having one or more carbon-carbon double bonds. Specific examples thereof include vinyl groups, allyl groups, hexenyl groups, and octenyl groups. Various examples of ethylenically unsaturated groups include CH₂═CH—, CH₂═CHCH₂—, CH₂═CH(CH₂)₄—, CH₂═CH(CH₂)₆—, CH₂═C(CH₃)CH₂—, H₂C═C(CH₃)—, H₂C═C(CH₃)—, H₂C═C(CH₃)CH₂—, H₂C═CHCH₂CH₂—, and H₂C═CHCH₂CH₂CH₂—. Typically, the double bond or ethylenic unsaturation is terminal in each R³.

In specific embodiments, each R¹ of component (B) is independently selected from alkyl groups having from 1 to 10, alternatively from 1 to 8, alternatively from 1 to 6, alternatively from 1 to 4, alternatively from 1 to 2, alternatively 1, carbon atom(s).

Subscript n defines the number of D siloxy units present in the linear organopolysiloxane of component (B), and may alternatively be referred to as the degree of polymerization of the linear organopolysiloxane. In certain embodiments, subscript n is from 10 to 1000, alternatively from 50 to 750, alternatively from 100 to 500, alternatively from 150 to 450, alternatively from 200 to 400, alternatively from 250 to 350.

The linear organopolysiloxane of component (B) can be exemplified by a dimethylpolysiloxane capped at both molecular terminals with dimethylvinylsiloxy groups, a methylphenylpolysiloxane capped at both molecular terminals with dimethylvinylsiloxy groups, and/or a copolymer of a methylphenylsiloxane and dimethylsiloxane capped at both molecular terminals with dimethylvinylsiloxy groups.

Alternatively, as a specific example of the linear organopolysiloxane of component (B), the linear organopolysiloxane may comprise or consist of an organopolysiloxane having the average formula: Vi (CH₃)₂SiO[(CH₃)₂SiO]ₙSi(CH₃)₂Vi, where Vi indicates vinyl and subscript n is defined above. With regard to this average formula, any methyl group may be replaced with a different monovalent hydrocarbon group, and any vinyl group may be replaced with any alkenyl group.

In specific embodiments, the viscosity of component (B) at 25° C. is from 10 to 100,000 mPa·s, alternatively from 10 to 10,000 mPa·s, alternatively from 50 to 10,000 mPa·s. Viscosity may be measured at 25° C. via a Brookfield LV DV-E viscometer with a spindle selected as appropriate to the viscosity of the substantially linear polyorganosiloxane, i.e., RV-1 to RV-7.

Component (B) may comprise a combination or two or more different linear organopolysiloxanes that differ in at least one property such as structure, molecular weight, degree of polymerization, viscosity, etc.

The composition typically comprises component (B) in an amount of from 1 to 60, alternatively from 2 to 55, alternatively from 5 to 50, alternatively from 5 to 40, alternatively from 7.5 to 35, weight percent based on the total weight of the composition.

The composition additionally comprises (C) a linear organohydrogenpolysiloxane having two silicon-bonded hydrogen atoms only on its molecular terminals. Said differently, component (C) does not include silicon-bonded hydrogen atoms in pendant positions, i.e., bonded to silicon atoms in D siloxy units. The linear organohydrogenpolysiloxane having hydrogen atoms bonded to silicon atoms only on its molecular terminals of component (C) acts as a crosslinking agent of the composition.

In specific embodiments, the linear organohydrogenpolysiloxane has average unit formula: (HR¹₂SiO_{1/2})(R¹₂SiO_{2/2})_{n′}(HR¹₂SiO_{1/2}), where each R¹ is independently selected and defined above, and subscript n′ is selected to give a viscosity of the linear organohydrogenpolysiloxane at 25° C. of from 2 to 10,000 mPa·s, alternatively from 10 to 10,000 mPa·s. In specific embodiments, subscript n′ is from 1 to 500, alternatively from 1 to 200, alternatively from 1 to 150, alternatively from 1 to 100, alternatively from 1 to 50, alternatively from 5 to 40, alternatively from 10 to 30.

In another specific embodiment, the linear organohydrogenpolysiloxane has the average formula:

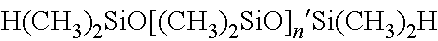

where n′ is as defined above. Component (C) may comprise a combination or two or more different linear organohydrogenpolysiloxanes that differ in at least one property such as structure, molecular weight, degree of polymerization, viscosity, etc.

The composition typically comprises component (C) in an amount of from 1 to 40, alternatively from 2 to 30, alternatively from 5 to 25, weight percent based on the total weight of the composition. Component (C) is typically present in an amount to give a molar ratio of silicon-bonded hydrogen atoms in component (C) to silicon-bonded alkenyl groups of component (B) and component (D) (described below) of from 0.2:1 to 5:1, alternatively from 0.8:1 to 1.2:1, moles of silicon-bonded hydrogen atoms of component (C) to the total moles of silicon-bonded alkenyl groups present in the other components of the composition.

In addition, the composition comprises (D) a Q-branched organopolysiloxane having at least three silicon-bonded alkenyl groups on its molecular terminals. By “Q-branched,” with reference to component (D), it is meant that branching in component (D) is imparted by a Q siloxy unit, i.e., SiO_{4/2}. The Q-branched organopolysiloxane of component (D) is represented by the following formula:

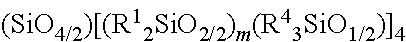

wherein each R¹ is independently selected and defined above; each R⁴ is independently R¹ or an alkenyl group having 2 to 10 carbon atoms, with the proviso that at least three of R⁴ are alkenyl groups; and each subscript m is independently a number from 5 to 200. Suitable examples of R¹ are described above, along with exemplary examples of alkenyl groups for R⁴.

The Q-branched organopolysiloxane generally comprises M siloxy units (i.e., the (R⁴₃SiO_{1/2}) siloxy units), D siloxy units (i.e., the (R¹₂SiO_{2/2}) siloxy units), and Q siloxy units (i.e., the (SiO_{4/2}) siloxy units). Although the Q-branched organopolysiloxane includes one Q siloxy unit, the Q-branched organopolysiloxane is considered a branched silicone polymer by one of skill in the art, rather than a silicone resin, due to the degree of polymerization (DP) in the Q-branched organopolysiloxane and the low molar fraction of Q siloxy units present therein.

The Q-branched organopolysiloxane has a degree of polymerization (DP) of from 20 to 800, alternatively from 50 to 600, alternatively from 100 to 400, alternatively from 150 to 350, alternatively from 175 to 325. As understood in the art, the DP of the Q-branched organopolysiloxane is the sum or aggregate of each m, which indicates the number of D siloxy units in each linear branch of the Q-branched organopolysiloxane. The Q-branched organopolysiloxane includes a Q unit having four linear chains consisting of D siloxy units capped with M siloxy units. Each linear chain has an independently selected subscript m, and thus the length or number of siloxy units in each linear chain is also independently selected. In certain embodiments, each subscript m is different. In other embodiments, each subscript m is the same.

The Q-branched organopolysiloxane of component (D) can also be represented by the following formula:

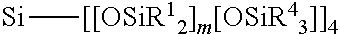

wherein each R¹ and R⁴ is independently selected and defined above, and each subscript m is independently selected and defined above.

In specific embodiments, each R¹ is methyl (Me), and each R⁴ is vinyl (Vi). In these embodiments, the Q-branched organopolysiloxane of component (D) has the general formula:

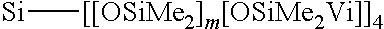

where m is independently selected and defined above. However, as noted above, the M siloxy units and/or D siloxy units may different from one another.

Regardless of the selection of the Q-branched organopolysiloxane of component (D), the Q-branched organopolysiloxane has at least three silicon-bonded alkenyl groups designated by R⁴. In certain embodiments, the Q-branched organopolysiloxane has a content of alkenyl groups designated by R⁴ of from greater than 0 to 7, alternatively from 0.1 to 6, wt. % based on the total weight of the Q-branched organopolysiloxane. This is typically the case when each R⁴ is vinyl and each R¹ is methyl. However, as understood in the art, the same number of alkenyl groups may constitute a lesser overall wt. % when R¹ is something other than methyl (e.g. ethyl, aryl) and/or when R² is something other than vinyl (e.g. allyl, hexenyl), which impact the molecular weight of the Q-branched organopolysiloxane. The content of R⁴ can be interpreted and calculated using Silicon 29 Nuclear Magnetic Resonance Spectroscopy (²⁹Si NMR), as understood in the art.

Combinations of different Q-branched organopolysiloxanes may be utilized together as component (D).

In certain embodiments, the Q-branched organopolysiloxane has a viscosity at 25° C. from greater than 0 to less than 12,000, alternatively from greater than 50 to 10,000, alternatively from greater than 50 to 7,500, alternatively from greater than 50 to 5,000, alternatively from greater than 50 to 2,500, alternatively from greater than 50 to less than 1,000, mPa·s.

The composition typically comprises component (D) in an amount of from 20 to 90, alternatively from 30 to 80, alternatively from 40 to 75, weight percent based on the total weight of the composition.

The composition further comprises (E) a hydrosilylation-reaction catalyst. The (E) hydrosilylation-reaction catalyst is not limited and may be any known hydrosilylation-reaction catalyst for catalyzing hydrosilylation reactions. Combinations of different hydrosilylation-reaction catalysts may be utilized.

The (E) hydrosilylation-reaction catalyst may be in or on a solid carrier. Examples of carriers include activated carbons, silicas, silica aluminas, aluminas, zeolites and other inorganic powders/particles (e.g. sodium sulphate), and the like. The (E) hydrosilylation-reaction catalyst may also be disposed in a vehicle, e.g. a solvent which solubilizes the (E) hydrosilylation-reaction catalyst, alternatively a vehicle which merely carries, but does not solubilize, the (E) hydrosilylation-reaction catalyst. Such vehicles are known in the art.

In specific embodiments, the (E) hydrosilylation-reaction catalyst comprises platinum. In these embodiments, the (E) hydrosilylation-reaction catalyst is exemplified by, for example, platinum black, compounds such as chloroplatinic acid, chloroplatinic acid hexahydrate, a reaction product of chloroplatinic acid and a monohydric alcohol, platinum bis(ethylacetoacetate), platinum bis(acetylacetonate), platinum chloride, and complexes of such compounds with olefins or organopolysiloxanes, as well as platinum compounds microencapsulated in a matrix or core-shell type compounds. Microencapsulated hydrosilylation catalysts and methods of their preparation are also known in the art, as exemplified in U.S. Pat. Nos. 4,766,176 and 5,017,654, which are incorporated by reference herein in their entireties.

Complexes of platinum with organopolysiloxanes suitable for use as the (E) hydrosilylation-reaction catalyst include 1,3-diethenyl-1,1,3,3-tetramethyldisiloxane complexes with platinum. These complexes may be microencapsulated in a resin matrix. Alternatively, the (E) hydrosilylation-reaction catalyst may comprise 1,3-diethenyl-1,1,3,3-tetramethyldisiloxane complex with platinum. The (E) hydrosilylation-reaction catalyst may be prepared by a method comprising reacting chloroplatinic acid with an aliphatically unsaturated organosilicon compound such as divinyltetramethyldisiloxane, or alkene-platinum-silyl complexes.

The (E) hydrosilylation-reaction catalyst may also, or alternatively, be a photoactivatable hydrosilylation-reaction catalyst, which may initiate curing via irradiation and/or heat. The photoactivatable hydrosilylation-reaction catalyst can be any hydrosilylation-reaction catalyst capable of catalyzing the hydrosilylation reaction, particularly upon exposure to radiation having a wavelength of from 150 to 800 nanometers (nm).

Specific examples of photoactivatable hydrosilylation-reaction catalysts suitable for the (E) hydrosilylation-reaction catalyst include, but are not limited to, platinum(II) β-diketonate complexes such as platinum(II) bis(2,4-pentanedioate), platinum(II) bis(2,4-hexanedioate), platinum(II) bis(2,4-heptanedioate), platinum(II) bis(1-phenyl-1,3-butanedioate, platinum(II) bis(1,3-diphenyl-1,3-propanedioate), platinum(II) bis(1,1,1,5,5,5-hexafluoro-2,4-pentanedioate); (n-cyclopentadienyl)trialkylplatinum complexes, such as (Cp)trimethylplatinum, (Cp)ethyldimethylplatinum, (Cp)triethylplatinum, (chloro-Cp)trimethylplatinum, and (trimethylsilyl-Cp)trimethylplatinum, where Cp represents cyclopentadienyl; triazene oxide-transition metal complexes, such as Pt[C₆H₅NNNOCH₃]₄, Pt[p-CN—C₆H₄NNNOC₆H₁₁]₄, Pt[p-H₃COC₆H₄NNNOC₆H₁₁]₄, Pt[p-CH₃(CH₂)ₓ—C₆H₄NNNOCH₃]₄, 1,5-cyclooctadiene.Pt[p-CN—C₆H₄NNNOC₆H₁₁]₂, 1,5-cyclooctadiene.Pt[p-CH₃O—C₆H₄NNNOCH₃]₂, [(C₆H₅)₃P]₃Rh[p-CN—C₆H₄NNNOC₆H₁₁], and Pd[p-CH₃(CH₂)ₓ—C₆H₄NNNOCH₃]₂, where x is 1, 3, 5, 11, or 17; (η-diolefin)(σ-aryl)platinum complexes, such as (η⁴-1,5-cyclooctadienyl)diphenylplatinum, η⁴-1,3,5,7-cyclooctatetraenyl)diphenylplatinum, (η⁴-2,5-norboradienyl)diphenylplatinum, (η⁴-1,5-cyclooctadienyl)bis-(4-dimethylaminophenyl)platinum, (η⁴-1,5-cyclooctadienyl)bis-(4-acetylphenyl)platinum, and (η⁴-1,5-cyclooctadienyl)bis-(4-trifluormethylphenyl)platinum. Typically, the photoactivatable hydrosilylation-reaction catalyst is a Pt(II) β-diketonate complex and more typically the catalyst is platinum(II) bis(2,4-pentanedioate).

The (E) hydrosilylation-reaction catalyst is present in the composition in a catalytic amount, i.e., an amount or quantity sufficient to promote curing thereof at desired conditions. The hydrosilylation-reaction catalyst can be a single hydrosilylation-reaction catalyst or a mixture comprising two or more different hydrosilylation-reaction catalysts.

The catalytic amount of the (E) hydrosilylation-reaction catalyst may be >0.01 ppm to 10,000 ppm; alternatively >1,000 ppm to 5,000 ppm. Alternatively, the typical catalytic amount of the (E) hydrosilylation-reaction catalyst is 0.1 ppm to 5,000 ppm, alternatively 1 ppm to 2,000 ppm, alternatively >1 ppm to 1,000 ppm. Alternatively, the catalytic amount of (E) hydrosilylation-reaction catalyst may be 0.01 ppm to 1,000 ppm, alternatively 0.01 ppm to 100 ppm, alternatively 20 ppm to 200 ppm, and alternatively 0.01 ppm to 50 ppm of platinum group metal; based on the total weight of composition.

In certain embodiments, the composition further comprises (F) an adhesion promoter. Suitable adhesion promoters may comprise a hydrocarbonoxysilane such as an alkoxysilane, a combination of an alkoxysilane and a hydroxy-functional polyorganosiloxane, an amino functional silane, an epoxy functional silane, a mercapto functional silane, or a combination thereof. Adhesion promoters are known in the art and may comprise silanes having the formula R⁵ₐR⁶_{b}Si(OR⁷)_{4-(a+b)} where each R⁵ is independently a monovalent organic group having at least 3 carbon atoms; R⁶ contains at least one SiC bonded substituent having an adhesion-promoting group, such as amino, epoxy, mercapto or acrylate groups; each R⁷ is independently a monovalent organic group (e.g. methyl, ethyl, propyl, butyl, etc.); subscript a has a value ranging from 0 to 2; subscript b is either 1 or 2; and the sum of (a+b) is not greater than 3. In certain embodiments, the (F) adhesion promoter comprises a partial condensate of the above silane. In these or other embodiments, the (F) adhesion promoter comprises a combination of an alkoxysilane and a hydroxy-functional polyorganosiloxane.

In some embodiments, the (F) adhesion promoter comprises an unsaturated or epoxy-functional compound. In such embodiments, the (F) adhesion promoter may be or comprise an unsaturated or epoxy-functional alkoxysilane such as those having the formula (XIII): R⁸_{c}Si(OR⁹)_{(4-c)}, where subscript c is 1, 2, or 3, alternatively subscript c is 1. Each R⁸ is independently a monovalent organic group with the proviso that at least one R⁸ is an unsaturated organic group or an epoxy-functional organic group. Epoxy-functional organic groups for R⁸ are exemplified by 3-glycidoxypropyl and (epoxycyclohexyl)ethyl. Unsaturated organic groups for R⁸ are exemplified by 3-methacryloyloxypropyl, 3-acryloyloxypropyl, and unsaturated monovalent hydrocarbon groups such as vinyl, allyl, hexenyl, undecylenyl. Each R⁹ is independently a saturated hydrocarbon group of 1 to 4 carbon atoms, alternatively 1 to 2 carbon atoms. R⁹ is exemplified by methyl, ethyl, propyl, and butyl.

Specific examples of suitable epoxy-functional alkoxysilanes include 3-glycidoxypropyltrimethoxysilane, 3-glycidoxypropyltriethoxysilane, (epoxycyclohexyl)ethyldimethoxysilane, (epoxycyclohexyl)ethyldiethoxysilane and combinations thereof. Examples of suitable unsaturated alkoxysilanes include vinyltrimethoxysilane, allyltrimethoxysilane, allyltriethoxysilane, hexenyltrimethoxysilane, undecylenyltrimethoxysilane, 3-methacryloyloxypropyl trimethoxysilane, 3-methacryloyloxypropyl triethoxysilane, 3-acryloyloxypropyl trimethoxysilane, 3-acryloyloxypropyl triethoxysilane, and combinations thereof.

In some embodiments, the (F) adhesion promoter comprises an epoxy-functional siloxane, such as a reaction product of a hydroxy-terminated polyorganosiloxane with an epoxy-functional alkoxysilane (e.g. such as one of those described above), or a physical blend of the hydroxy-terminated polyorganosiloxane with the epoxy-functional alkoxysilane. The (F) adhesion promoter may comprise a combination of an epoxy-functional alkoxysilane and an epoxy-functional siloxane. For example, the (F) adhesion promoter is exemplified by a mixture of 3-glycidoxypropyltrimethoxysilane and a reaction product of hydroxy-terminated methylvinylsiloxane with 3-glycidoxypropyltrimethoxysilane, or a mixture of 3-glycidoxypropyltrimethoxysilane and a hydroxy-terminated methylvinylsiloxane, or a mixture of 3-glycidoxypropyltrimethoxysilane and a hydroxy-terminated methylvinyl/dimethylsiloxane copolymer.

In certain embodiments, the (F) adhesion promoter comprises an aminofunctional silane, such as an aminofunctional alkoxysilane exemplified by H₂N(CH₂)₂Si(OCH₃)₃, H₂N(CH₂)₂Si(OCH₂CH₃)₃, H₂N(CH₂)₃Si(OCH₃)₃, H₂N(CH₂)₃Si(OCH₂CH₃)₃, CH₃NH(CH₂)₃Si(OCH₃)₃, CH₃NH(CH₂)₃Si(OCH₂CH₃)₃, CH₃NH(CH₂)₅Si(OCH₃)₃, CH₃NH(CH₂)₅Si(OCH₂CH₃)₃, H₂N(CH₂)₂NH(CH₂)₃Si(OCH₂CH₃)₃, H₂N(CH₂)₂NH(CH₂)₃Si(OCH₃)₃, CH₃NH(CH₂)₂NH(CH₂)₃Si(OCH₃)₃, C₄H₉NH(CH₂)₂NH(CH₂)₃Si(OCH₃)₃, CH₃NH(CH₂)₂NH(CH₂)₃Si(OCH₂CH₃)₃, C₄H₉NH(CH₂)₂NH(CH₂)₃Si(OCH₂CH₃)₃, H₂N(CH₂)₂SiCH₃(OCH₃)₂, H₂N(CH₂)₂SiCH₃(OCH₂CH₃)₂, H₂N(CH₂)₃SiCH₃(OCH₃)₂, H₂N(CH₂)₃SiCH₃(OCH₂CH₃)₂, CH₃NH(CH₂)₃SiCH₃(OCH₃)₂, CH₃NH(CH₂)₅SiCH₃(OCH₃)₂, CH₃NH(CH₂)₃SiCH₃(OCH₂CH₃)₂, CH₃NH(CH₂)₅SiCH₃(OCH₂CH₃)₂, H₂N(CH₂)₂NH(CH₂)₃SiCH₃(OCH₃)₂, H₂N(CH₂)₂NH(CH₂)₃SiCH₃(OCH₂CH₃)₂, CH₃NH(CH₂)₂NH(CH₂)₃SiCH₃(OCH₃)₂, CH₃NH(CH₂)₂NH(CH₂)₃SiCH₃(OCH₂CH₃)₂, C₄H₉NH(CH₂)₂NH(CH₂)₃SiCH₃(OCH₃)₂, C₄H₉NH(CH₂)₂NH(CH₂)₃SiCH₃(OCH₂CH₃) 2, N-(3-(trimethoxysilyl) propyl)ethylenediamine, and the like, as well as combinations thereof. In these or other embodiments, the (F) adhesion promoter comprises a mercaptofunctional alkoxysilane, such as 3-mercaptopropyltrimethoxysilane or 3-mercaptopropyltriethoxysilane.

Additional examples of adhesion promoters include the reaction product of an epoxyalkylalkoxysilane, such as 3-glycidoxypropyltrimethoxysilane, and an amino-substituted alkoxysilane, such as 3-aminopropyltrimethoxysilane, optionally with an alkylalkoxysilane, such as methyltrimethoxysilane.

An exemplary adhesion promoter comprises a reaction mixture of an organoalkoxysilane containing an amino group and an organoalkoxysilane containing an epoxy group. Such a reaction mixture is disclosed in Japanese Patent Application Publication S52-8854 B and Japanese Unexamined Patent Application Publication H10-195085 A.

The ratio of the alkoxysilane having an amino group containing organic group to the alkoxysilane having an epoxy group containing organic group is, in terms of the molar ratio, is typically within the range of (1:1.5) to (1:5), alternatively within the range of (1:2) to (1:4). This component can be easily synthesized by mixing alkoxysilane having an amino group containing organic group and alkoxysilane having an epoxy group containing organic group as mentioned above to cause them to react at room temperature or by heating.

In particular, when an alkoxysilane having an amino group containing organic group is reacted with an alkoxysilane having an epoxy group containing organic group by the method described in Japanese Unexamined Patent Application H10-195085A, the present invention may contain a carbasilatrane derivative obtained by cyclizing by an alcohol exchange reaction and expressed by the general formula:

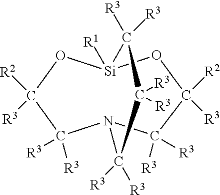

where R¹ is an alkyl group, alkenyl group, or an alkoxy group, and R² is the same or different group selected from the group consisting of groups expressed by the general formula:

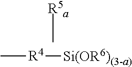

where R⁴ is an alkylene group or alkyleneoxyalkylene group, R⁵ is a monovalent hydrocarbon group, R⁶ is an alkyl group, and a is 0, 1, or 2), or

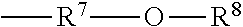

where R⁷ is an alkylene group, R⁸ is an alkyl group, alkenyl group, or acyl group, and R³ is the same or different hydrogen atom or alkyl group. Examples of carbasilatrane derivatives may include carbasilatrane derivatives having a silicon-bonded alkoxy group or a silicon-bonded alkenyl group per molecule represented by the following structure.

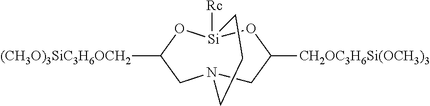

where Rc is a group selected from methoxy groups, ethoxy groups, vinyl groups, allyl groups and hexenyl groups.

Furthermore, in the present invention, a silatran derivative as represented by the following structural formula may be utilized as an adhesion-imparting agent:

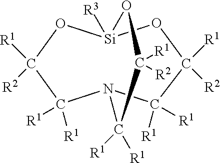

wherein R¹ in the formula is the same or a different hydrogen atom or alkyl group, and R¹ is typically a hydrogen atom or a methyl group. Furthermore, R² in the aforementioned formula is the same or different group selected from a collection consisting of a hydrogen atom, alkyl groups, and organic group containing an alkoxysilyl group as expressed by the general formula:

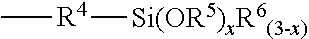

where at least one of the R² is the organic group containing an alkoxysilyl group. Examples of the alkyl group of R² include methyl groups and the like. Furthermore, in the organic group containing an alkoxysilyl group of R², R⁴ in the formula is a divalent organic group, and examples include alkylene groups or alkyleneoxyalkylene groups. An ethylene group, a propylene group, a butylene group, a methyleneoxypropylene group, and a methyleneoxypentylene group are typical. Furthermore, R⁵ in the formula is an alkyl group having 1 to 10 carbon atoms, and is generally a methyl group or an ethyl group. Furthermore, R⁶ in the formula is a substituted or unsubstituted monovalent hydrocarbon group, and typically a methyl group. Furthermore, x in the formula is 1, 2, or 3, and typically 3.

Examples of such an organic group containing an alkoxysilyl group of R² include the following groups.

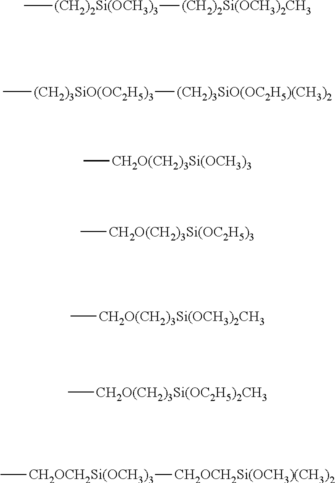

When utilized, the (F) adhesion promoter is present in the composition in an amount of from greater than 0 to 3, alternatively from 0.001 to 2.0, weight percent based on the total weight of the composition.

In certain embodiments, the composition further comprises (G) a reaction product between (g1) an alkali metal silanolate and (g2) at least one salt selected from chloride salt represented by M¹Cl_{y} and carboxylate salt represented by (R⁵COO)_{y}M¹, where each R⁵ is same or different monovalent hydrocarbon group, M¹ is cerium or a rare earth metal mixture comprising cerium as major component, and y ranges from 1 to 3 depending on the valency of M¹. By “major component,” it is meant that the rare earth metal mixture comprises cerium in an amount greater than that of any other rare earth metal present in the mixture.

Component (G), if utilized, is used for enhancing heat resistance of the composition and cured product formed therefrom. In specific embodiments, component (G) contains from 0.5 to 5.0 mass % of cerium (metal). The alkali metal silanolate (g1) is typically an alkali metal silanolate compound obtained by subjecting at least one cyclic organopolysiloxane to a ring opening reaction using an alkali metal hydroxide, and then subjecting the resulting product to a further reaction with an organopolysiloxane having a viscosity ranging from 10 to 1,000,000, alternatively from 100 to 10,000 mPa·s at 25° C. The cyclic organopolysiloxane is not particularly limited, and typically includes from 3 to 8 siloxy units. Examples of cyclic organopolysiloxanes include hexamethyl cyclotrisiloxane (D3), octamethyl cyclotetrasiloxane (D4), decamethyl cyclopentasiloxane (D5), dodecamethyl-cyclohexasiloxane (D6), 1,1-diethylhexamethyl cyclotetrasiloxane, phenylheptamethyl cyclotetrasiloxane, 1,1-diphenylhexamethyl cyclotetrasiloxane, 1,3,5,7-tetravinyltetramethyl cyclotetrasiloxane, 1,3,5,7-tetramethyl cyclotetrasiloxane, 1,3,5,7-tetracyclohexyltetramethyl cyclotetrasiloxane, tris(3,3,3-trifluoropropyl)trimethylcyclotrisiloxane, 1,3,5,7-tetra (3-methacryloxypropyl) tetramethyl cyclotetrasiloxane, 1,3,5,7-tetra (3-acryloxypropyl) tetramethyl cyclotetrasiloxane, 1,3,5,7-tetra (3-carboxypropyl) tetramethyl cyclotetrasiloxane, 1,3,5,7-tetra (3-vinyloxypropyl) tetramethyl cyclotetrasiloxane, 1,3,5,7-tetra (p-vinylphenyl) tetramethyl cyclotetrasiloxane, 1,3,5,7-tetra [3-(p-vinylphenyl) propyl] tetramethyl cyclotetrasiloxane, 1,3,5,7-tetra (N-acryloyl-N-methyl-3-aminopropyl) tetramethyl cyclotetrasiloxane, 1,3,5,7-tetra (N,N-bis(lauryl)-3-aminopropyl) tetramethyl cyclotetrasiloxane, and the like. Furthermore, a mixture of different cyclic organopolysiloxanes may be utilized.

The alkali metal hydroxide is not particularly limited, and examples thereof include a sodium hydroxide, potassium hydroxide, and the like. The amount of alkali metal hydroxide is typically from 0.1 to 10.0 parts by mass per 100 parts by mass of the cyclic organopolysiloxane.

Any conventionally known organopolysiloxanes having a viscosity at 25° C. in a range of 100 to 1,000,000 mPa·s can be used as the organopolysiloxane to form the alkali metal silanolate (g1), and the organopolysiloxane is substantially a linear or branched organopolysiloxane that is liquid at room temperature and has repeating diorganopolysiloxane units (linear-chain structure) as a main constituent. The organic groups bonded to silicon atoms (i.e, substituted or unsubstituted monovalent hydrocarbon group) can be the same organic group exemplified above. Examples of the organopolysiloxanes include organopolysiloxanes having molecular terminals capped with triorganosiloxy groups including trialkylsiloxy groups such as a trimethylsiloxy group, alkenyldialkylsiloxy groups such as a vinyldimethylsiloxy group, dialkenylalkylsiloxy groups such as a divinylmethylsiloxy group, trialkenylsiloxy groups such as a trivinylsiloxy group, and the like, or an organopolysiloxane having molecular terminals capped with a hydroxyl group, alkoxy group, or the like.

The salt of component (g2) is a chloride salt represented by M¹Cl_{y} or a carboxylate salt represented by (R⁵COO)_{y}M¹, where each R⁵ is same or different monovalent hydrocarbon group, M¹ is cerium or a rare earth metal mixture comprising cerium as major component, and y ranges from 1 to 3 depending on the valency of M¹. M¹ represents cerium or a mixture of rare earth elements containing cerium as a main component, and examples include ceric salts of 2-ethylhexanoic acid, naphthenic acid, oleic acid, lauric acid, stearic acid, and the like. The carboxylic acid salt may be used as an organic solvent solution. Examples of the organic solvent include petroleum based-solvent such as a standard solvent, mineral spirits, ligroin, and petroleum ether, and aromatic solvent such as toluene and xylene.

The amount of the salt of component (g2) is not particularly limited, but is typically utilized in an amount to provide a content of M¹ of from 0.05 to 5 parts by mass, alternatively from 0.1 to 3 parts by mass, per 100 parts total mass of the component (g1) described above. Component (G) can be obtained by mixing components (g1) and (g2) and then heat-treating the mixture at a temperature of 150° C. or higher. The heating temperature of the heat treatment is typically from 150 to 310° C., alternatively from 200 to 305° C., alternatively from 250 to 300° C.

When utilized, component (G) is present in the composition in an amount of from greater than 0 to 3, alternatively from 0.001 to 2.0, weight percent based on the total weight of the composition.

The curable silicone composition of the present invention may further contain (H) a filler and/or (I) a pigment. The (H) filler is not limited and may be, for example, a reinforcing filler, an extending filler, a thermally conductive filler, an electrically conductive filler, a flame retarding filler, an acid accepting filler, a rheologically modifying filler, a phosphor, a coloring filler, a mineral filler, a glass filler, a carbon filler, or a combination thereof. The selection of the (H) filler is typically a function of the cured product to be formed with the composition and the end use applications of the cured product.

The (H) filler may be untreated, pretreated, or added in conjunction with an optional filler treating agent, described below, which when so added may treat the (H) filler in situ or prior to incorporation of the (H) filler in the composition. The (H) filler may be a single filler or a combination of two or more fillers that differ in at least one property such as type of filler, method of preparation, treatment or surface chemistry, filler composition, filler shape, filler surface area, average particle size, and/or particle size distribution.

The shape and dimensions of the (H) filler and/or the (I) pigment is also not specifically restricted. For example, the (H) filler may be spherical, rectangular, ovoid, irregular, and may be in the form of, for example, a powder, a flour, a fiber, a flake, a chip, a shaving, a strand, a scrim, a wafer, a wool, a straw, a particle, and combinations thereof. Dimensions and shape are typically selected based on the type of the (H) filler utilized, the selection of other components included within the composition, and the end use application of the cured product formed therewith.

Non-limiting examples of fillers that may function as reinforcing fillers include reinforcing silica fillers such as fume silica, silica aerogel, silica xerogel, and precipitated silica. Fumed silicas are known in the art and commercially available, e.g., fumed silica sold under the name CAB-O-SIL by Cabot Corporation of Massachusetts, U.S.A.

Non-limiting examples fillers that may function as extending or reinforcing fillers include quartz and/or crushed quartz, aluminum oxide, magnesium oxide, silica (e.g. fumed, ground, precipitated), hydrated magnesium silicate, magnesium carbonate, dolomite, silicone resin, wollastonite, soapstone, kaolinite, kaolin, mica muscovite, phlogopite, halloysite (hydrated alumina silicate), aluminum silicate, sodium aluminosilicate, glass (fiber, beads or particles, including recycled glass, e.g. from wind turbines or other sources), clay, magnetite, hematite, calcium carbonate such as precipitated, fumed, and/or ground calcium carbonate, calcium sulfate, barium sulfate, calcium metasilicate, zinc oxide, talc, diatomaceous earth, iron oxide, clays, mica, chalk, titanium dioxide (titania), zirconia, sand, carbon black, graphite, anthracite, coal, lignite, charcoal, activated carbon, non-functional silicone resin, alumina, silver, metal powders, magnesium oxide, magnesium hydroxide, magnesium oxysulfate fiber, aluminum trihydrate, aluminum oxyhydrate, coated fillers, carbon fibers (including recycled carbon fibers, e.g. from the aircraft and/or automotive industries), poly-aramids such as chopped KEVLAR™ or Twaron™, nylon fibers, mineral fillers or pigments (e.g. titanium dioxide, non-hydrated, partially hydrated, or hydrated fluorides, chlorides, bromides, iodides, chromates, carbonates, hydroxides, phosphates, hydrogen phosphates, nitrates, oxides, and sulfates of sodium, potassium, magnesium, calcium, and barium; zinc oxide, antimony pentoxide, antimony trioxide, beryllium oxide, chromium oxide, lithopone, boric acid or a borate salt such as zinc borate, barium metaborate or aluminum borate, mixed metal oxides such as vermiculite, bentonite, pumice, perlite, fly ash, clay, and silica gel; rice hull ash, ceramic and, zeolites, metals such as aluminum flakes or powder, bronze powder, copper, gold, molybdenum, nickel, silver powder or flakes, stainless steel powder, tungsten, barium titanate, silica-carbon black composite, functionalized carbon nanotubes, cement, slate flour, pyrophyllite, sepiolite, zinc stannate, zinc sulphide), and combinations thereof. Alternatively, the extending or reinforcing filler may be selected from the group consisting of calcium carbonate, talc and a combination thereof.

As known in the art, certain fillers may serve as pigments. By way of example, white pigment can comprise include metal oxides such as titanium oxide, aluminum oxide, zinc oxide, zirconium oxide, magnesium oxide, and the like; hollow fillers such as glass balloons, glass beads, and the like; and additionally, barium sulfate, zinc sulfate, barium titanate, aluminum nitride, boron nitride, and antimony oxide. Such components can be considered fillers and/or pigments.

Extending fillers are known in the art and commercially available, such as a ground silica sold under the name MIN-U-SIL by U.S. Silica of Berkeley Springs, WV. Suitable precipitated calcium carbonates include Winnofil™ SPM from Solvay and Ultra-pflex™ and Ultra-pflex™ 100 from SMI.

When the (H) filler comprises a thermally conductive filler, the (H) filler may be both thermally conductive and electrically conductive. Alternatively, the (H) filler may be thermally conductive and electrically insulating. A thermally conductive filler may also have other beneficial properties, such as, but not limited to, a reinforcing filler, an extending filler, or another property as described above. The thermally conductive filler may be selected from, but not limited to, the group consisting of aluminum nitride, aluminum oxide, aluminum trihydrate, aluminum oxyhydrate, barium titanate, barium sulfate, beryllium oxide, carbon fibers, diamond, graphite, magnesium hydroxide, magnesium oxide, magnesium oxysulfate fiber, metal particulate, onyx, silicon carbide, tungsten carbide, zinc oxide, coated fillers, and a combination thereof.

When the (H) filler comprises the thermally conductive filler, the thermally conductive filler may comprise a metallic filler, an inorganic filler, a meltable filler, or a combination thereof. Metallic fillers include particles of metals, metal powders, and particles of metals having layers on the surfaces of the particles. These layers may be, for example, metal nitride layers or metal oxide layers. Suitable metallic fillers are exemplified by particles of metals selected from the group consisting of aluminum, copper, gold, nickel, silver, and combinations thereof, and alternatively aluminum. Suitable metallic fillers are further exemplified by particles of the metals listed above having layers on their surfaces selected from the group consisting of aluminum nitride, aluminum oxide, copper oxide, nickel oxide, silver oxide, and combinations thereof. For example, the metallic filler may comprise aluminum particles having aluminum oxide layers on their surfaces. Inorganic fillers are exemplified by onyx; aluminum trihydrate, aluminum oxyhydrate, metal oxides such as aluminum oxide, beryllium oxide, magnesium oxide, and zinc oxide; nitrides such as aluminum nitride; carbides such as silicon carbide and tungsten carbide; and combinations thereof. Alternatively, inorganic fillers are exemplified by aluminum oxide, zinc oxide, and combinations thereof. Meltable fillers may comprise Bi, Ga, In, Sn, or an alloy thereof. The meltable filler may optionally further comprise Ag, Au, Cd, Cu, Pb, Sb, Zn, or a combination thereof. Examples of suitable meltable fillers include Ga, In—Bi—Sn alloys, Sn—In—Zn alloys, Sn—In—Ag alloys, Sn—Ag—Bi alloys, Sn—Bi—Cu—Ag alloys, Sn—Ag—Cu—Sb alloys, Sn—Ag—Cu alloys, Sn—Ag alloys, Sn—Ag—Cu—Zn alloys, and combinations thereof. The meltable filler may have a melting point from 50° C. to 250° C. The meltable filler may be a eutectic alloy, a non-eutectic alloy, or a pure metal. Many suitable meltable fillers are commercially available.

Alternatively or in addition, the (H) filler may comprise a non-reactive silicone resin other than component (A). For example, the (H) filler may comprise a T resin, a TD resin, a TDM resin, a TDMQ resin, or any other non-reactive silicone resin. Typically, such non-reactive silicone resins include at least 30 mole percent T siloxy and/or Q siloxy units. As known in the art, D siloxy units are represented by R⁰₂SiO_{2/2}, and T siloxy units are represented by R⁰SiO_{3/2}, where R⁰ is an independently selected substituent.

The weight average molecular weight, M_{w}, of the non-reactive silicone resin will depend at least in part on the molecular weight of the silicone resin and the type(s) of substituents (e.g. hydrocarbyl groups) that are present in the non-reactive silicone resin. M_{w} as used herein represents the weight average molecular weight measured using conventional gel permeation chromatography (GPC), with narrow molecular weight distribution polystyrene (PS) standard calibration, when the peak representing the neopentamer is excluded from the measurement. The PS equivalent M_{w} of the non-reactive silicone resin may be from 12,000 to 30,000 g/mole, typically from 17,000 to 22,000 g/mole. The non-reactive silicone resin can be prepared by any suitable method. Silicone resins of this type have been prepared by cohydrolysis of the corresponding silanes or by silica hydrosol capping methods generally known in the art.

Phosphor is a type of filler that can convert the emission wavelength from a light source (optical semiconductor device) when the cured product of the composition is used as a wavelength conversion material. There is no particular limitation on this phosphor, and examples of the phosphor include yellow, red, green, and blue light phosphors, which include oxide phosphors, oxynitride phosphors, nitride phosphors, sulfide phosphors, oxysulfide phosphors, and the like, which are widely used in light emitting diodes (LED).

In certain embodiments, the (H) filler may comprise an acid acceptor. The acid acceptor may comprise a metal oxide such as magnesium oxide. Acid acceptors are generally known in the art and are commercially available under trade names including Rhenofit F, Star Mag CX-50, Star Mag CX-150, BLP-3, and MaxOx98LR. Rhenofit F was calcium oxide from Rhein Chemie Corporation of Chardon, Ohio, USA. Star Mag CX-50 was magnesium oxide from Merrand International Corp. of Portsmouth, N.H., USA. MagOX 98LR was magnesium oxide from Premier Chemicals LLC of W. Conshohocken, Pa., USA. BLP-3 was calcium carbonate was Omya Americas of Cincinnati, Ohio, USA.

Regardless of the selection of the (H) filler, the (H) filler may be untreated, pretreated, or added to form the composition in conjunction with an optional filler treating agent, which when so added may treat the (H) filler in situ in the composition.

The filler treating agent may comprise a silane such as an alkoxysilane, an alkoxy-functional oligosiloxane, a cyclic polyorganosiloxane, a hydroxyl-functional oligosiloxane such as a dimethyl siloxane or methyl phenyl siloxane, an organosilicon compound, a stearate, or a fatty acid. The filler treating agent may comprise a single filler treating agent, or a combination of two or more filler treating agents selected from similar or different types of molecules.

The filler treating agent may comprise an alkoxysilane, which may be a mono-alkoxysilane, a di-alkoxysilane, a tri-alkoxysilane, or a tetra-alkoxysilane. Alkoxysilane filler treating agents are exemplified by hexyltrimethoxysilane, octyltriethoxysilane, decyltrimethoxysilane, dodecyltrimethoxysilane, tetradecyltrimethoxysilane, phenyltrimethoxysilane, phenylethyltrimethoxysilane, octadecyltrimethoxysilane, octadecyltriethoxysilane, and a combination thereof. In certain aspects the alkoxysilane(s) may be used in combination with silazanes, which catalyze the less reactive alkoxysilane reaction with surface hydroxyls. Such reactions are typically performed above 100° C. with high shear with the removal of volatile by-products such as ammonia, methanol and water.

Suitable filler treating agents also include alkoxysilyl functional alkylmethyl polysiloxanes, or similar materials where the hydrolyzable group may comprise, for example, silazane, acyloxy or oximo.

Alkoxy-functional oligosiloxanes can also be used as filler treating agents. Alkoxy-functional oligosiloxanes and methods for their preparation are generally known in the art. Other filler treating agents include mono-endcapped alkoxy functional polydiorganosiloxanes, i.e., polyorganosiloxanes having alkoxy functionality at one end.

Alternatively, the filler treating agent can be any of the organosilicon compounds typically used to treat silica fillers. Examples of organosilicon compounds include organochlorosilanes such as methyltrichlorosilane, dimethyldichlorosilane, and trimethyl monochlorosilane; organosiloxanes such as hydroxy-endblocked dimethylsiloxane oligomer, silicon hydride functional siloxanes, hexamethyldisiloxane, and tetramethyldivinyldisiloxane; organosilazanes such as hexamethyldisilazane and hexamethylcyclotrisilazane; and organoalkoxysilanes such as alkylalkoxysilanes with Methyl, Propyl, n-Butyl, i-Butyl, n-Hexyl, n-Octyl, i-Octyl, n-Decyl, dodecyl, tetradecyl, hexadecyl, or octadecyl substituents. Organoreactive alkoxysilanes can include amino, methacryloxy, vinyl, glycidoxy, epoxycyclohexyl, isocyanurato, isocyanato, mercapto, sulfido, vinyl-benzyl-amino, benzyl-amino, or phenyl-amino substituents. Alternatively, the filler treating agent may comprise an organopolysiloxane. The use of such a filler treating agent to treat the surface of the (H) filler may take advantage of multiple hydrogen bonds, either clustered or dispersed or both, as the method to bond the organosiloxane to the surface of the (H) filler. The organosiloxane capable of hydrogen bonding has an average, per molecule, of at least one silicon-bonded group capable of hydrogen bonding. The group may be selected from: a monovalent organic group having multiple hydroxyl functionalities or a monovalent organic group having at least one amino functional group. Hydrogen bonding may be a primary mode of bonding of the organosiloxane to the (H) filler. The organosiloxane may be incapable of forming covalent bonds with the (H) filler. The organosiloxane capable of hydrogen bonding may be selected from the group consisting of a saccharide-siloxane polymer, an amino-functional organosiloxane, and a combination thereof. Alternatively, the polyorganosiloxane capable of hydrogen bonding may be a saccharide-siloxane polymer.

Alternatively, the filler treating agent may comprise alkylthiols such as octadecyl mercaptan and others, and fatty acids such as oleic acid, stearic acid, titanates, titanate coupling agents, zirconate coupling agents, and a combination thereof. One skilled in the art could optimize a filler treating agent to aid dispersion of the (H) filler without undue experimentation.

If utilized, the relative amount of the filler treatment agent and the (H) filler is selected based on the particular filler utilized as well as the filler treatment agent, and desired effect or properties thereof.

The amount of component (H) is not restricted, but when utilized, the composition typically comprises component (H) in an amount from 10 to 2,000 mass parts, alternatively from 10 to 1500 mass parts, alternatively from 10 to 1000 mass parts with regards to the sum of component (A)-(D) (100 mass parts).

In certain embodiments, the composition further comprises an inhibitor. The inhibitor may be used for altering the reaction rate or curing rate of the composition, as compared to a composition containing the same starting materials but with the inhibitor omitted. The inhibitor is exemplified by acetylenic alcohols such as methyl butynol, ethynyl cyclohexanol, dimethyl hexynol, and 3,5-dimethyl-1-hexyn-3-ol, 1-butyn-3-ol, 1-propyn-3-ol, 2-methyl-3-butyn-2-ol, 3-methyl-1-butyn-3-ol, 3-methyl-1-pentyn-3-ol, 3-phenyl-1-butyn-3-ol, 4-ethyl-1-octyn-3-ol, and 1-ethynyl-1-cyclohexanol, and a combination thereof; cycloalkenylsiloxanes such as methylvinylcyclosiloxanes exemplified by 1,3,5,7-tetramethyl-1,3,5,7-tetravinylcyclotetrasiloxane, 1,3,5,7-tetramethyl-1,3,5,7tetrahexenylcyclotetrasiloxane, and a combination thereof; ene-yne compounds such as 3-methyl-3-penten-1-yne, 3,5-dimethyl-3-hexen-1-yne; triazoles such as benzotriazole; phosphines; mercaptans; hydrazines; amines, such as tetramethyl ethylenediamine, dialkyl fumarates, dialkenyl fumarates, dialkoxyalkyl fumarates, maleates such as diallyl maleate; nitriles; ethers; carbon monoxide; alkenes such as cyclo-octadiene, divinyltetramethyldisiloxane; alcohols such as benzyl alcohol; and a combination thereof. Alternatively, the inhibitor may be selected from the group consisting of acetylenic alcohols (e.g., 1-ethynyl-1-cyclohexanol) and maleates (e.g., diallyl maleate, bis maleate, or n-propyl maleate) and a combination of two or more thereof.

Alternatively, the inhibitor may be a silylated acetylenic compound. Without wishing to be bound by theory, it is thought that adding a silylated acetylenic compound reduces yellowing of the reaction product prepared from hydrosilylation reaction of the composition as compared to a reaction product from hydrosilylation of a composition that does not contain a silylated acetylenic compound or that contains an organic acetylenic alcohol inhibitor, such as those described above.

The silylated acetylenic compound is exemplified by (3-methyl-1-butyn-3-oxy)trimethylsilane, ((1,1-dimethyl-2-propynyl)oxy)trimethylsilane, bis(3-methyl-1-butyn-3-oxy)dimethylsilane, bis(3-methyl-1-butyn-3-oxy) silanemethylvinylsilane, bis((1,1-dimethyl-2-methyl(tris(1,1-dimethyl-2-propynyloxy)) silane, methyl(tris(3-propynyl)oxy)dimethylsilane, methyl-1-butyn-3-oxy)) silane, (3-methyl-1-butyn-3-oxy)dimethylphenylsilane, (3-methyl-1-butyn-3-oxy)dimethylhexenylsilane, (3-methyl-1-butyn-3-oxy)triethylsilane, bis(3-methyl-1-butyn-3-oxy)methyltrifluoropropylsilane, (3,5-dimethyl-1-hexyn-3-oxy)trimethylsilane, (3-phenyl-1-butyn-3-oxy)diphenylmethylsilane, (3-phenyl-1-butyn-3-oxy)dimethylphenylsilane, (3-phenyl-1-butyn-3-oxy)dimethylvinylsilane, (3-phenyl-1-butyn-3-oxy)dimethylhexenylsilane, (cyclohexyl-1-ethyn-1-oxy)dimethylhexenylsilane, (cyclohexyl-1-ethyn-1-oxy)dimethylvinylsilane, (cyclohexyl-1-ethyn-1-oxy)diphenylmethylsilane, (cyclohexyl-1-ethyn-1-oxy)trimethylsilane, and combinations thereof. Alternatively, the inhibitor is exemplified by methyl(tris(1,1-dimethyl-2-propynyloxy)) silane, ((1,1-dimethyl-2-propynyl)oxy)trimethylsilane, or a combination thereof. The silylated acetylenic compound useful as the inhibitor may be prepared by methods known in the art, such as silylating an acetylenic alcohol described above by reacting it with a chlorosilane in the presence of an acid receptor.

The amount of the inhibitor present in the composition will depend on various factors including the desired pot life of the composition, whether the composition will be a one-part composition or a multiple part composition, the particular inhibitor used, and the selection and amount of components (A)-(D). However, when present, the amount of the inhibitor may be 0% to 1%, alternatively 0% to 5%, alternatively 0.001% to 1%, alternatively 0.01% to 0.5%, and alternatively 0.0025% to 0.025%, based on the total weight of the composition.

The composition can further comprise (K) an organopolysiloxane or an organosiloxane oligomer other than component (A), wherein the (K) organopolysiloxane or organosiloxane oligomer does not include hydrosilylation-reactive functional groups. As known in the art, hydrosilylation-reactive functional groups are silicon-bonded organic groups having aliphatic unsaturation (i.e., alkenyl and alkynyl groups) and silicon-bonded hydrogen atoms. When utilized, component (K) can be an oligomer, a polymer, a partly-branched polymer, a branched polymer, or a three-dimensional network (i.e., a resin). Component (K) can comprise any combination of M, D, T, and Q siloxy units. If utilized, component (K), like component (A), does not participate in the hydrosilylation reaction to cure the composition and give the cured product, i.e., the silicone gel.

In certain embodiments, the composition comprises organopolysiloxanes other than components (B)-(D) and having hydrosilylation-reactive functional groups in an amount of less than 10, alternatively less than 9.5, alternatively less than 9.0, alternatively less than 8.5, alternatively less than 8.0, alternatively less than 7.5, alternatively less than 7.0, alternatively less than 6.5, alternatively less than 6.0, alternatively less than 5.5, alternatively less than 5.0, alternatively less than 4.5, alternatively less than 4.0, alternatively less than 3.5, alternatively less than 3.0, alternatively less than 2.5, alternatively less than 2.0, alternatively less than 1.5, alternatively less than 1.0, alternatively less than 0.5, alternatively 0, wt. % based on the total weight of the composition.

In some embodiments, the composition further comprises a heat resistance improving agent other than component (G). The other resistance improving agent is exemplified by iron oxide (red iron oxide), cerium oxide, cerium dimethyl silanolate, fatty acid cerium salt, cerium hydroxide, zirconium compound, copper (Cu) phthalocyanine or a combination thereof.

In some embodiments, the composition further comprises one or more additives. Examples of suitable additives that may be present in the composition include fillers, treating agents (e.g. filler treating agents), cross-linkers, adhesion promotors, surface modifiers, drying agents, extenders, biocides, flame retardants, plasticizers, end-blockers, binders, anti-aging additives, water release agents, pigments, dyes, rheology modifiers, carriers, tackifying agents, corrosion inhibitors, catalyst inhibitors, viscosity modifiers, UV absorbers, anti-oxidants, light-stabilizers, and the like, as well as combinations thereof.

In certain embodiments, the composition and silicone gel formed by curing the composition are substantially transparent.

The composition can be cured to give a cured product in the form of a silicone gel having excellent physical properties, including resistance to cracking upon exposure to elevated temperatures for extended periods of time. Because the occurrence of bubbles and cracks can be suppressed, the silicone gel has excellent bonding properties to electrical or electronic parts.

The cured product or silicone gel typically has a Shore 000 hardness of from 10 to 100, alternatively from 50 to 90, alternatively from 70 to 90. Shore 000 durometer can be measured according to ASTM D2240.

The composition is typically cured by exposing the composition to an elevated temperature. The elevated temperature is not particularly limited, but is normally from 60° C. to 150° C., alternatively from 70° C. to 130° C. Alternatively, the composition can be cured at ambient conditions, such as room temperature, i.e., without exposing the composition to an elevated temperature.

The silicone gel has excellent heat resistance at high temperatures of 180° C. and above, and the silicone gel does not tend to deteriorate when used for a long period at high temperature. Furthermore, when used in applications for protecting electronic components such as semiconductor chips, SiC semiconductor chips, ICs, hybrid ICs and power devices, the occurrence of air bubbles and cracks in the silicone gel can be suppressed even under high-temperature conditions, and further, because the silicone gel has good bonding to electrical or electronic parts, the silicone gel has the advantage of being able to provide electrical or electronic parts with high reliability and stability. Furthermore, because the silicone gel of the present invention is transparent, light-emitting semiconductor elements such as LEDs may be included in the above semiconductor chips. Thus, the silicone gel is particularly suited for use as an encapsulant agent for an electronic article.

The method for sealing or filling an electrical or electronic part with the composition to form the encapsulant agent for the electrical or electronic parts is not limited, but an example is contacting the portion of the electrical or electronic part to be protected with the composition, and then curing the composition by heating it, letting it stand at room temperature, or irradiating it with ultraviolet light, thus resulting in the electrical or electronic part having an encapsulant agent that is the silicone gel formed from the composition.

The electrical or electronic part that is sealed, filled, or encapsulated by the silicone gel of the present invention is not limited, but because the silicone gel of the present invention can suppress the occurrence of air bubbles and cracks and exhibits good bonding to electrical or electronic parts even under high-temperature conditions, it can be advantageously used in power devices used under high-temperature conditions, particularly power devices such as a motor control, a motor control for transport, a power generation system, or a space transportation system. Furthermore, because the silicone gel of the present invention has a certain degree of cold resistance in addition to the heat resistance demanded in an SiC semiconductor chip (for example, heat resistance of 180° C. or above), it can be advantageously used in power devices that demand the ability to withstand sharp temperature differences, and can improve the durability and reliability of such power devices. Examples of such power devices that demand heat resistance and cold resistance include motor controls used in cold regions such as general-purpose inverter controls, servo motor controls, machine tools or elevators, electric vehicles, hybrid cars or motor controls for rail transport used in cold regions, power generating systems used in cold regions such as solar, wind or fuel cell power generators, space transportation systems used in space, and the like. “Cold regions” are regions where the temperature falls below 0° C. Furthermore, the encapsulant agent for electrical or electronic parts of the present invention is also effective in electrical or electronic parts having a structure in which the space between electrodes, between electrical elements or between an electrical element and the package in the electrical or electronic part is narrow, or having a structure in which these structures cannot track to the expansion and contraction of the silicone gel. For example, it may be used in electrical circuits or modules on which electrical elements such as semiconductor elements, capacitors and resistors are mounted, i.e., various sensors such as pressure sensors that are generally sealed or filled with silicone gel, and automotive igniters, regulators and the like. The electronic article may be a photoelectronic device, and the electronic article may be mounted on a general lighting device, ad display article, an optical article, or a photoelectronic article, for example.

Examples of such electrical or electronic parts are the same as the electrical or electronic parts described above, particularly power devices such as a motor control, a motor control for transport, a power generation system, or a space transportation system.

The protection method for a semiconductor chip according to the present invention is a method for protecting a semiconductor chip by using the silicone gel of the present invention, an example of which is a protection method for a semiconductor chip that uses the sealant for electrical or electronic parts of the present invention as a sealant. By this protection method for a semiconductor chip, electrical or electronic parts, particularly power devices, having high reliability and stability even under high-temperature conditions can be provided because it uses the silicone gel of the present invention.

The following examples are intended to illustrate the invention and are not to be viewed in any way as limiting to the scope of the invention.

Certain components utilized in the Examples are set forth in Table 1 below.

TABLE 1
Components/Compounds Utilized:

| Abbreviation | Meaning/Definition |
|---|---|
| Organopolysiloxane Resin | Trimethylsilyl MQ Resin of average formula M_{0.47}T^{oz}_{0.03}Q^{0.50} |
| (A1) | with a molecular weight of 14,000-20,000 g/mol (65 wt. %) in |
| | Xylene (35 wt. %), where Z is alkyl or a hydrogen atom. |
| Organopolysiloxane Resin | Trimethylsilyl MQ Resin of average formula |
| (A2) | M_{0.47}T^{oz}_{0.03}Q_{0.50} with a molecular weight of 14,000-20,000 |
| | g/mol, where Z is alkyl or a hydrogen atom. |
| MQ Blend | Blend of MQ Resin of average formula M_{0.47}T^{oz}_{0.03}Q_{0.50} |
| | with a molecular weight of 14,000-20,000 g/mol (40 wt. %) |
| | compounded with Linear Organopolysiloxane (B1) (60 wt. %), |
| | where Z is alkyl or a hydrogen atom, as prepared in |
| | Preparation Example 1. |
| Linear Organopolysiloxane | Vinyl Terminated Siloxane of average formula M^{vi}D₃₁₀M^{vi} |
| (B1) | |
| Linear | SiH Terminated Siloxane of average formula M^{H}D₂₀M^{H} |
| Organohydrogenpolysiloxane | |
| (C1) | |
| Q-branched | Vinyl Terminated Q-Branch Siloxane of average formula |
| organopolysiloxane (D1) | Q(D-₅₅M^{vi})₄ |
| Hydrosilylation Reaction | Karstedt's Catalyst |
| Catalyst (E1) | |
| Adhesion Promoter (F1) | Bi(trimethoxysilyl)hexane |
| Thermal Stabilizer (G1) | Dimethylsiloxane cerium salt with polydimethylsiloxane |
| Comparative Siloxane (X1) | Vinyl MQ Resin of average formula M^{vi}_{0.05}M_{0.37}Q_{0.58} with a |
| | molecular weight 14,000-20,000 g/mol (36 wt. %) |
| | compounded with Linear Organopolysiloxane (B1) (64 wt. %) |
| Comparative Siloxane (X2) | Polydimethylsiloxane (PDMS) with a viscosity at 25° C. of 1000 |
| | mPa · s |

### Preparation Example 1

A three-neck round bottom flask equipped with stir-mechanism, nitrogen sweep, thermocouple, and water-cooled condenser was provided. An organopolysiloxane resin linear mixture was prepared by combining 50.6 parts by weight Organopolysiloxane Resin (A1) and 49.4 parts by weight Linear Organopolysiloxane (B1) in the flask. The organopolysiloxane resin linear mixture was heated to 80° C. and blended until a homogeneous mixture was formed. The homogeneous mixture was cooled to room temperature and then transferred to an addition funnel of a wipe film evaporator. The jacket of the wipe film evaporator was heated to 150° C. and a pull vacuum of <1 mmHg was applied. The rotor blades of the wipe film evaporator were then turned on, and the homogeneous mixture was gradually fed through the wipe film evaporator via metered addition. The volatiles were then discarded and the non-volatiles were collected. The collected non-volatiles are referred to as an MQ Blend. The MQ Blend contained less than 2 wt. % volatile content, and specifically less than 0.3 wt. % QM₄ neopentamer, which was confirmed via GC-analysis.

### General Procedure 1: Examples 1-5

Compositions are prepared for Examples 1-5 in accordance with General Procedure 1. In General Procedure 1, a Dynamic Axial Centrifuge (DAC Mixer) and a plastic container compatible therewith was provided. The following intermediates were loaded into the plastic container in specified amounts (as shown in the Tables below): MQ Blend, Q-branched organopolysiloxane (D1), and Linear Organohydrogenpolysiloxane (C1). The intermediates were then mixed in the DAC Mixer for 30 seconds at 2,000 revolutions per minute (RPM). The walls of the plastic container were then scraped to remove intermediates from the walls. The mixing step was repeated until a homogeneous blend was achieved. Hydrosilylation Reaction Catalyst (E1) was then added to the plastic container and mixed with the other intermediates in the DAC Mixer for 30 seconds at 2,000 RPM. The mixing step was repeated until a homogeneous blend was achieved to give a curable silicone-based gel composition.

### General Procedure 2: Examples 6-7

Compositions are prepared for Examples 6-7 in accordance with General Procedure 2. In General Procedure 2, a Dynamic Axial Centrifuge (DAC Mixer) and a plastic container compatible therewith was provided. The following intermediates were loaded into the plastic container in specified amounts (as shown in the Tables below): MQ Blend, Q-branched organopolysiloxane (D1), and Linear Organohydrogenpolysiloxane (C1). The intermediates were then mixed in the DAC Mixer for 30 seconds at 2,000 RPM. The walls of the plastic container were then scraped to remove intermediates from the walls. The mixing step was repeated until a homogeneous blend was achieved. Adhesion Promoter (F1), Thermal Stabilizer (G1), and Hydrosilylation Reaction Catalyst (E1) were then added to the plastic container and mixed with the other intermediates in the DAC Mixer for 30 seconds at 2,000 RPM. The mixing step was repeated until a homogeneous blend was achieved to give a curable silicone-based gel composition.

TABLE 2
Compositions of Examples 1-4

| | Example 1 | Example 2 | Example 3 | Example 4 |
|---|---|---|---|---|
| Organopolysiloxane | 6.00 | 10.00 | 13.20 | 15.00 |
| Resin (A2) | | | | |
| (in the MQ Blend) | | | | |
| Linear | 9.00 | 15.00 | 19.80 | 12.50 |
| Organopolysiloxane | | | | |
| (B1) (in the | | | | |
| MQ Blend) | | | | |
| Linear | 11.80 | 10.80 | 10.00 | 9.50 |
| Organohydrogen- | | | | |
| polysiloxane (C1) | | | | |
| Q-branched | 73.00 | 64.00 | 56.80 | 52.80 |
| organopolysiloxane | | | | |
| (D1) | | | | |
| Hydrosilylation | 0.20 | 0.20 | 0.20 | 0.20 |
| Reaction | | | | |
| Catalyst (E1) | | | | |
| Total Parts: | 100.00 | 100.00 | 100.00 | 100.00 |
| SiH:SiVi molar | 0.846 | 0.851 | 0.855 | 0.853 |
| ratio: | | | | |

TABLE 3
Compositions of Examples 5-7

| | Example 5 | Example 6 | Example 7 |
|---|---|---|---|
| Organopolysiloxane | 20.00 | 10.00 | 13.20 |
| Resin (A2) (in the MQ | | | |
| Blend) | | | |
| Linear | 30.00 | 15.00 | 19.80 |
| Organopolysiloxane | | | |
| (B1) (in the MQ Blend) | | | |
| Linear | 8.20 | 10.75 | 9.90 |
| Organohydrogenpolysiloxane | | | |
| (C1) | | | |
| Q-branched | 41.60 | 63.30 | 56.15 |
| organopolysiloxane | | | |
| (D1) | | | |
| Hydrosilylation | 0.20 | 0.20 | 0.20 |
| Reaction | | | |
| Catalyst (E1) | | | |
| Adhesion | — | 0.20 | 0.20 |
| Promoter (F1) | | | |
| Thermal | — | 0.55 | 0.55 |
| Stabilizer (G1) | | | |
| Total Parts: | 100.00 | 100.00 | 100.00 |
| SiH:SiVi molar | 0.855 | 0.855 | 0.855 |
| ratio | | | |

### General Procedure 3: Comparative Examples 1-4

Compositions are prepared for Comparative Examples 1˜4 in accordance with General Procedure 3. In General Procedure 3, a Dynamic Axial Centrifuge (DAC Mixer) and a plastic container compatible therewith was provided. The following intermediates were loaded into the plastic container in specified amounts (as shown in Table 4 below): optionally Comparative Siloxane (X1), optionally Comparative Siloxane (X2), optionally MQ Blend, Q-branched organopolysiloxane (D1), and Linear Organohydrogenpolysiloxane (C1). The intermediates were then mixed in the DAC Mixer for 30 seconds at 2,000 RPM. The walls of the plastic container were then scraped to remove intermediates from the walls. The mixing step was repeated until a homogeneous blend was achieved. Hydrosilylation Reaction Catalyst (E1) was then added to the plastic container and mixed with the other intermediates in the DAC Mixer for 30 seconds at 2,000 RPM. The mixing step was repeated until a homogeneous blend was achieved to give a comparative curable silicone-based gel composition.

TABLE 4
Compositions of Comparative Examples 1-4

| | Comparative | Comparative | Comparative | Comparative |
|---|---|---|---|---|
| | Example 1 | Example 2 | Example 3 | Example 4 |
| Organopolysiloxane | — | — | 3.00 | — |
| Resin (A2) (in MQ Blend) | | | | |
| Linear | — | — | 4.50 | — |
| Organopolysiloxane | | | | |
| (B1) (in MQ Blend) | | | | |
| Linear | 14.50 | 12.00 | 12.60 | 10.10 |
| Organohydrogenpolysiloxane | | | | |
| (C1) | | | | |
| Q-branched | 57.50 | 87.80 | 79.70 | 64.70 |
| organopolysiloxane | | | | |
| (D1) | | | | |
| Hydrosilylation | 0.20 | 0.20 | 0.20 | 0.20 |
| Reaction | | | | |
| Catalyst (E1) | | | | |
| Comparative | 27.80 | — | — | — |
| Siloxane (X1) | | | | |
| Comparative | — | — | — | 25.00 |
| Siloxane (X2) | | | | |
| Total Parts: | 100.00 | 100.00 | 100.00 | 100.00 |

The compositions of Examples 1-7 and Comparative Examples 1˜4 were cured to give cured silicone gels and analyzed as described below.

### Cure and Thermal Stability Testing

The compositions of Examples 1-7 and Comparative Examples 1˜4 were mixed on the DAC mixer at 500 RPM for 30 seconds to eliminate any air-bubbles. For each composition, a 20 g aliquot was carefully poured into a clean and dry Pyrex™ petri dish, and seven 10 g aliquots were carefully poured into clean Al dishes. Each composition was cured on a level surface for 48 hours under ambient conditions (22° C. and 48% relative humidity to give a cured gel.

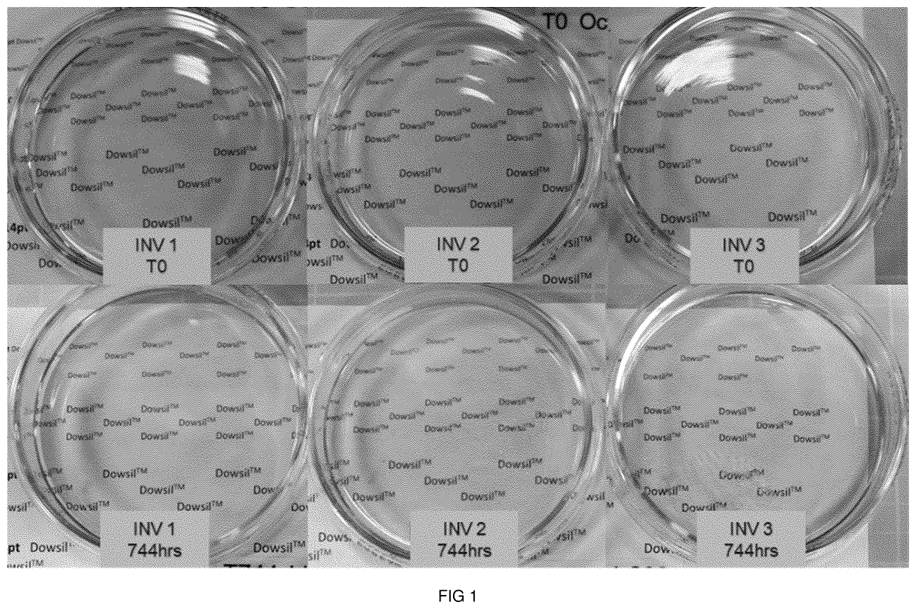

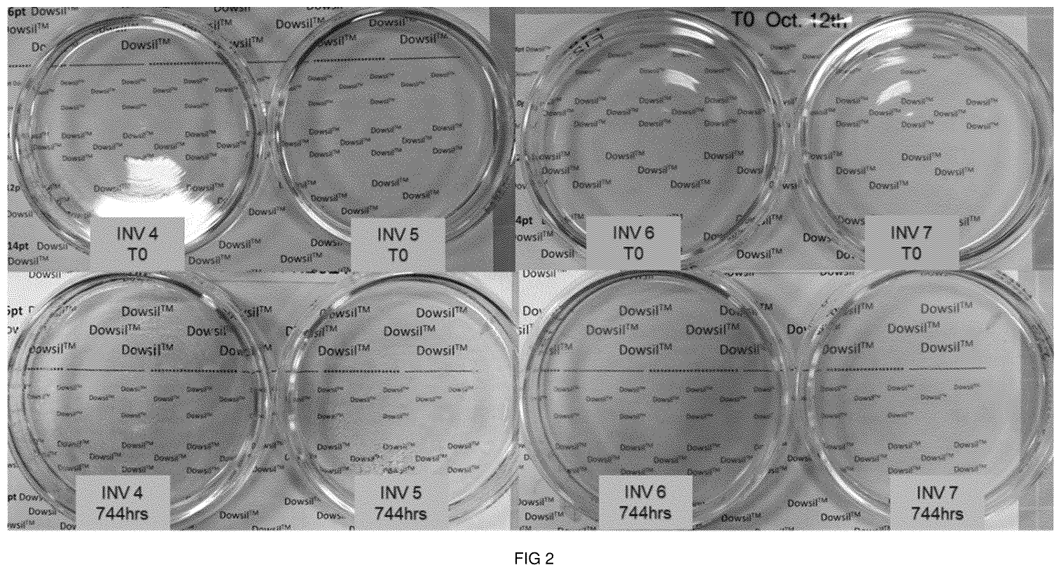

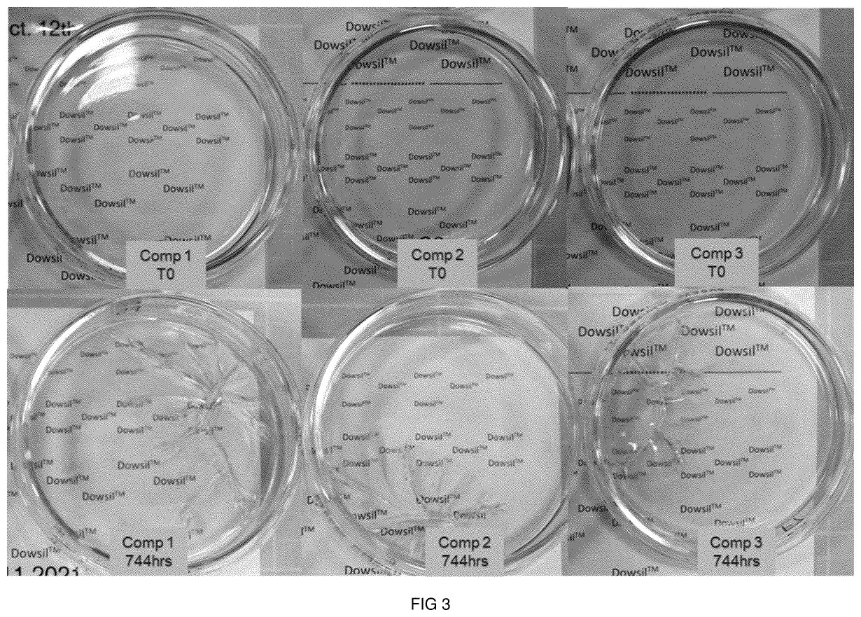

Initial (T0) observations were collected for the cured gels. Shore 000 durometer was measured according to ASTM D2240, and the cured gels were inspected for clarity and the presence of any cracks, bubbles, or other imperfections. Cured gels samples in Al dishes were placed in a 150° C. convection oven, and cured gel samples in Pyrex™ petri dishes were placed on hot plates with a surface temperature of 200° C. Samples were monitored periodically over the course of the study: samples were tested for Shore 000 durometer and observed for cracks, bubbles, and other defects; pictures were captured using a camera and are shown as FIGS. 1-3, illustrating the cured gels of Examples 1-7 and Comparative Examples 1-3 both initially and after thermal aging for 744 hours. The thermal stability study was performed over a period of 744 hours (31 days).

### Rheology Test Method

Rheology data were obtained using an Anton Paar MCR-302 Rheometer. Gel curing and rheology tests were performed at 25° C. using 25 mm parallel plates. The previously described cured gels were mixed on the DAC mixer at 500 rpm for 30 secs to eliminate air bubbles. An aliquot was loaded onto the rheometer. Curing of the gel recipes was ensured by monitoring the viscoelastic properties; once the gel recipes cured, viscoelastic properties showed no significant change. Then, viscoelastic data sets were obtained at 1 Hz by applying strains within the linear viscoelastic regions.

The results of the thermal stability testing, summarized in Tables 5-7 below, demonstrate superior thermal stability of Examples 1-7 over the Comparative Examples 1-3. Unlike the cured gels of Examples 1-7, those of Comparative Examples 1-3 failed the thermal stability test and showed crack formation by the 744 hr mark when: Comparative Siloxane (X1) is substituted for the MQ Blend as in Comparative Example 1; the Organopolysiloxane Resin (A2) is eliminated as in Comparative Example 2; or an insufficient 3 wt. % loading of the Organopolysiloxane Resin (A2) as in Comparative Example 3. In Tables 5-7 below, TO indicates gel quality upon formation (i.e., at time zero), and T744 hr indicates gel quality after aging for 744 hours at 200° C. on a hot plate.

Damping property was assessed using the rheological property, Tan Delta. Tan Delta represents the ratio of the viscous to elastic response of a material (G″/G′), or the energy dissipation potential of the material. The larger the Tan Delta value, the higher the damping property. The rheological properties are summarized in Tables 5-7, below. Addition of Organopolysiloxane Resin (A2) systematically increased the damping property; as the content of Organopolysiloxane Resin (A2) increases from 3 to 20 wt. % as shown in Comparative Example 3 and Examples 1-5, the Tan Delta value increased from 0.10 to 0.19. Comparative Example 4 had 25 wt. % of Comparative Siloxane (X2) as a non-functional ingredient while Example 5 had a comparable content (20 wt. %) of non-functional MQ resin (i.e., Organopolysiloxane Resin (A2)). Despite the comparable addition of non-functional ingredients, the Tan Delta value of Example 5 was higher than that of Comparative Example 4 without any significant compromise in G′.

TABLE 5
Properties if Examples 1-4

| Measurement/ | | | | | |
|---|---|---|---|---|---|
| Observation | Criteria | Example 1 | Example 2 | Example 3 | Example 4 |
| Gel Quality - T0 | Crack-Free | Pass | Pass | Pass | Pass |
| Gel Quality - T744 hr | Crack-Free | Pass | Pass | Pass | Pass |
| Shore 000 - T0 | N/A | 80.4 | 76.8 | 78.4 | 76.2 |
| Shore 000 - T744 hr | N/A | 75.0 | 79.6 | 75.2 | 73.6 |
| Shore 000 % Change | <+5% | −6.7% | 3.6% | −4.1% | −3.4% |
| G′ [Pa] | N/A | 36,843 | 35,705 | 33,663 | 30,996 |
| G″ [Pa] | >3,000 | 3,788 | 4,061 | 4,218 | 4,294 |
| Tan Delta [—] | ≥0.10 | 0.10 | 0.11 | 0.13 | 0.14 |

TABLE 6
Properties of Examples 5-7

| Measurement/ | | | | |
|---|---|---|---|---|
| Observation | Criteria | Example 5 | Example 6 | Example 7 |
| Gel Quality - T0 | Crack-Free | Pass | Pass | Pass |
| Gel Quality - T744 hr | Crack-Free | Pass | Pass | Pass |
| Shore 000 - T0 | N/A | 75.6 | 78.2 | 79.0 |
| Shore 000 - T744 hr | N/A | 73.4 | 76.8 | 79.0 |
| Shore 000 % Change | <+5% | −2.9% | −1.8% | 0.0% |
| G′ [Pa] | N/A | 24,104 | 36,187 | 31,633 |
| G″ [Pa] | >3,000 | 4,501 | 3,991 | 3,957 |
| Tan Delta [—] | ≥0.10 | 0.19 | 0.11 | 0.13 |

TABLE 7
Properties of Comparative Examples 1-4

| Measurement/ | | Comparative | Comparative | Comparative | Comparative |
|---|---|---|---|---|---|
| Observation | Criteria | Example 1 | Example 2 | Example 3 | Example 4 |
| Gel Quality - T0 | Crack-Free | Pass | Pass | Pass | Pass |
| Gel Quality - T744 hr | Crack-Free | Fail | Fail | Fail | Pass |
| Shore 000 - T0 | N/A | 77.2 | 68.0 | 82.2 | 74.2 |
| Shore 000 - T744 hr | N/A | 86.8 | 73.4 | 78.6 | 73.4 |
| Shore 000 % Change | <+5% | 12.4% | 7.9% | −4.4% | −1.1% |
| G′ [Pa] | | 70,622 | 10,205 | 38,633 | 24,570 |
| G″ [Pa] | >3,000 | 4,104 | 2,020 | 3,635 | 2,203 |
| Tan Delta [—] | >0.10 | 0.06 | 0.20 | 0.09 | 0.09 |

1. A curable silicone-based gel composition, comprising:
(A) an organopolysiloxane resin having a mass loss when component (A) is exposed for 1 hour at 200° C. of 2.0 mass % or less, and represented by following formula: 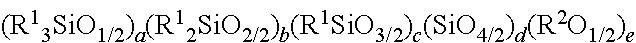
wherein each R¹ is independently a monovalent hydrocarbon group having 1 to 10 carbon atoms and not having aliphatic unsaturation in the group; each R₂ is independently a hydrogen atom or an alkyl group having 1 to 10 carbon atoms; and a, b, c, d and e are numbers satisfying the following: 0.10≤a≤0.60, 0.0≤b≤0.70, 0.0≤c≤0.80, 0.10≤d≤0.65, 0≤e≤0.05, and a+b+c+d=1;
(B) a linear organopolysiloxane having two silicon-bonded alkenyl groups only on its molecular terminals and represented by following formula: 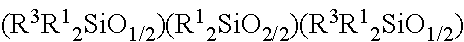
wherein each R¹ is independently selected and defined above; each R³ is independently an alkenyl group having 2 to 10 carbon atoms; and subscript n is a number from 10 to 1000;
(C) a linear organohydrogenpolysiloxane having two silicon-bonded hydrogen atoms only on its molecular terminals and a viscosity at 25° C. of 2 to 10,000 mPa·s;
(D) a Q-branched organopolysiloxane having at least three silicon-bonded alkenyl groups on its molecular terminals and represented by the following formula: 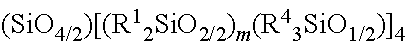
wherein each R¹ is independently selected and defined above; each R⁴ is independently R¹ or an alkenyl group having 2 to 10 carbon atoms with the proviso that at least three of R⁴ are alkenyl groups; and each subscript m is independently a number from 5 to 200; and
(E) a hydrosilylation reaction catalyst in an amount satisfying the curing reaction among components (A) to (D).

2. The curable silicone-based gel composition according to claim 1, wherein the amount for component (A) ranges from 5 to 25% by mass,
the amount for component (B) ranges from 5 to 50% by mass,
the amount for component (C) ranges from 5 to 25% by mass,
the amount for component (D) ranges from 30 to 80% by mass, and
the amount for component (E) ranges from 0.001 to 1.0% by mass as platinum-group metal, when the total mass of components (A) to (E) in the composition is 100% by mass.

3. The curable silicone-based gel composition according to claim 1, further comprising at least one selected from the group consisting of:
(F) an adhesion promoter; or
(G) a reaction product between (g1) an alkali metal silanolate and (g2) at least one salt selected from chloride salt represented by M¹Cl_{y} or carboxylate salt represented by (R⁵COO)_{y}M¹, where each R⁵ is same or different monovalent hydrocarbon group, M¹ is cerium or a rare earth metal mixture comprising cerium as major component, y ranges from 1 to 3 depending on the valency of M¹;
wherein the amount for component (F) or component (G) is from 0.001 to 2.0% by mass relative to the total mass of components (A) to (E) as 100% by mass in the composition.

4. The curable silicone-based gel composition according to claim 1, further comprising at least one selected from the group consisting of:
(H) an inorganic filler, which is optionally treated with at least one surface treating agent and/or optionally compounded with other components;
(I) a pigment; or
(J) an organopolysiloxane different than component (A) or an organosiloxane oligomer, wherein said organopolysiloxane or organosiloxane oligomer of component (K) do not include hydrosilylation-reactive functional group including aliphatic unsaturation in the molecule.

5. The curable silicone-based gel composition according to claim 1, comprising a content of organopolysiloxanes having hydrosilylation-reactive functional group other than components (B) to (D) is from 0.0 to 10.0% by mass relative to the total mass of components (A) to (E) as 100% by mass in the composition.

6. An encapsulant agent for an electronic article comprising the curable silicone-based gel composition according to claim 1.

7. The encapsulant agent for an electronic article according to claim 6, which is substantially transparent.

8. A silicone-based gel prepared by curing the curable silicone-based gel composition according to claim 1, the silicone-based gel having a Shore 000 hardness ranging from 10 to 100.

9. The silicone-based gel according to claim 8, which is substantially transparent.

10. An electronic article comprising the encapsulant agent according to claim 6.

11. The electronic article according to claim 10, which is mounted on a power device.

12. The electronic article according to claim 10, wherein the electronic article is a photoelectronic device.

13. The electronic article according to claim 12, which is mounted on a general lighting device, display article, optical article or photoelectronic article.

14. A protection method for semiconductor chip, which is characterized by using the curable silicone-based gel composition according to claim 1.

15. The curable silicone-based gel composition according to claim 2, further comprising at least one selected from the group consisting of:
(F) an adhesion promoter; or
(G) a reaction product between (g1) an alkali metal silanolate and (g2) at least one salt selected from chloride salt represented by M1Cly or carboxylate salt represented by (R5COO)yM1, where each R5 is same or different monovalent hydrocarbon group, M1 is cerium or a rare earth metal mixture comprising cerium as major component, y ranges from 1 to 3 depending on the valency of M1;
wherein the amount for component (F) or component (G) is from 0.001 to 2.0% by mass relative to the total mass of components (A) to (E) as 100% by mass in the composition.

16. The curable silicone-based gel composition according to claim 15, further comprising at least one selected from the group consisting of:
(H) an inorganic filler, which is optionally treated with at least one surface treating agent and/or optionally compounded with other components;
(I) a pigment; or
(J) an organopolysiloxane different than component (A) or an organosiloxane oligomer, wherein said organopolysiloxane or organosiloxane oligomer of component (K) do not include hydrosilylation-reactive functional group including aliphatic unsaturation in the molecule.
